(19) United States
(12) Patent Application Publication
(10) Pub. No.: US 2025/0336431 A1
(43) Pub. Date: Oct. 30, 2025

(54) MEMORY DEVICE, POWER SUPPLY METHOD, CHARGE PUMP CIRCUIT AND SYSTEM

(71) Applicant: Yangtze Memory Technologies Co., Ltd., Wuhan (CN)

(72) Inventors: Kang TAN, Wuhan (CN); Wei XUE, Wuhan (CN)

(21) Appl. No.: 18/892,121

(22) Filed: Sep. 20, 2024

(30) Foreign Application Priority Data
Apr. 28, 2024 (CN) 202410527007.2

(51) Int. Cl. G11C 11/4074; G11C 11/4076; G11C 11/408; H02M 3/07

(52) U.S. Cl. CPC G11C 11/4074; G11C 11/4076; G11C 11/4085; H02M 3/071

(57) ABSTRACT

The present application disclose memory devices, power supply methods, charge pump circuits, and systems. An example memory device includes: a memory cell array including rows of memory cells and a word line coupled to each row of memory cells, and a peripheral circuit coupled with a corresponding row of memory cells via the word line and including a first power supply circuit and a second power supply circuit. The first power supply circuit is configured to start outputting a first voltage to a substrate of a first transistor included in a first word line drive circuit coupled to a first unselected word line at a first time instant. The second power supply circuit is configured to start outputting a second voltage to a terminal of the first transistor at a second time instant. The first time instant is earlier than the second time instant.

### CROSS-REFERENCE TO RELATED APPLICATIONS

This application claims priority to Chinese Patent Application No. 202410527007.2, filed on Apr. 28, 2024, which is hereby incorporated by reference in its entirety.

### TECHNICAL FIELD

The present application relates to the field of semiconductor storage technology, and particularly to a memory device, a power supply method, a charge pump circuit, and a system.

### BACKGROUND

A memory device, especially a dynamic random access memory (DRAM), is widely applied in various electronic apparatuses, such as a computer, a wireless communication device, a camera, a digital display, and the like, to store related data. At present, a voltage overshoot may occur in the DRAM due to a coupling effect during the power-on process.

### SUMMARY

In view of this, examples of the present application provide a memory device, a power supply method, a charge pump circuit, and a system.

In order to achieve the above purpose, the technical solution of the present application is implemented as follows:

In a first aspect, examples of the present application provide a memory device comprising: a memory cell array comprising a plurality of rows of memory cells and a word line coupled to each of the plurality of rows of memory cells; and a peripheral circuit coupled with a corresponding row of memory cells via the word line and comprising a first power supply circuit and a second power supply circuit, wherein the first power supply circuit is configured to start outputting a first voltage to a substrate of a first transistor that is comprised in a first word line drive circuit coupled to a first unselected word line at a first time instant; and the second power supply circuit is configured to start outputting a second voltage to a terminal of the first transistor at a second time instant, wherein the first time instant is earlier than the second time instant.

In the above solution, the first voltage and the second voltage are negative voltages.

In the above solution, the second voltage is provided to a source terminal of the first transistor.

In the above solution, the plurality of rows of memory cells comprise a plurality of memory cells, and each of the plurality of memory cells comprises a second transistor and a capacitor, wherein a first terminal of the second transistor is connected with a terminal of the capacitor, a second terminal of the second transistor is connected with a bit line corresponding to the second transistor, and a control terminal of the second transistor is connected with a word line corresponding to the second transistor, wherein the first power supply circuit is further configured to provide the first voltage to a substrate of the second transistor.

In the above solution, the first power supply circuit is further configured to start outputting the first voltage in response to a first enable signal at the first time instant; after a first duration, a voltage value of the first voltage reaches a preset voltage value; and then after a second duration, the voltage value of the first voltage reaches a first target voltage value.

In the above solution, the second power supply circuit is further configured to start outputting the second voltage in response to a second enable signal at the second time instant; and after a third duration, a voltage value of the second voltage reaches a second target voltage value.

In the above solution, the second time instant corresponds to a time instant at which the voltage value of the first voltage ramps to the preset voltage value.

In the above solution, a ratio of the preset voltage value to the first target voltage value is between 50% and 90%.

In the above solution, the peripheral circuit further comprises a third power supply circuit, wherein the first power supply circuit is further configured to start outputting the first voltage to a substrate of a third transistor that is comprised in a second word line drive circuit coupled with a second unselected word line at the first time instant; and the third power supply circuit is configured to start outputting a third voltage to a terminal of the third transistor at a third time instant, wherein the first time instant is earlier than the third time instant.

In the above solution, the third voltage is provided to a source terminal of the third transistor.

In the above solution, the memory cell array comprises a plurality of memory blocks, and each of the plurality of memory blocks comprises the plurality of rows of memory cells and the word line coupled to each of the plurality of rows of memory cells, wherein the second unselected word line comprises a word line belonging to the same memory block as a selected word line.

In the above solution, the second unselected word line further comprises at least part of word lines that are comprised in a memory block adjacent to a memory block in which the selected word line is located.

In the above solution, the first unselected word line comprises an unselected word line other than the second unselected word line.

In the above solution, the third voltage is a negative voltage, and an absolute value of a third target voltage value of the third voltage is greater than a second target voltage value of the second voltage.

In the above solution, the first power supply circuit comprises a first comparator and a voltage generator, wherein the first comparator is configured to compare a reference voltage with a first feedback voltage, and output a first control signal according to a comparison result; the first feedback voltage is obtained according to the first voltage output by the voltage generator; and the voltage generator is configured to output the first voltage according to the first control signal.

In the above solution, the first power supply circuit further comprises: a feedback generator configured to receive the first voltage and output the first feedback voltage according to the first voltage; and a reference generator configured to output the reference voltage.

In the above solution, the feedback generator comprises: a fourth transistor, and a plurality of first resistors connected in series, wherein the first voltage is input to a first terminal of the fourth transistor, and a second terminal of the fourth transistor is connected with a first terminal of the plurality of first resistors; and a first initial voltage is input to a second terminal of the plurality of first resistors, wherein at the first time instant, a first enable signal is input to a control terminal of the fourth transistor, and the feedback generator outputs the first feedback voltage that is a voltage between two of the plurality of first resistors.

In the above solution, the feedback generator further comprises a fifth transistor and a sixth transistor, wherein a first sub-voltage comprised in the first initial voltage is input to a first terminal of the fifth transistor, and a second terminal of the fifth transistor is connected with the second terminal of the plurality of first resistors; a second sub-voltage comprised in the first initial voltage is input to a first terminal of the sixth transistor, and a second terminal of the sixth transistor is connected with the second terminal of the plurality of first resistors, wherein a second control signal is input to a control terminal of the fifth transistor, and the first power supply circuit operates in a first mode; and a third control signal is input to a control terminal of the sixth transistor, and the first power supply circuit operates in a second mode.

In the above solution, the reference generator comprises a plurality of second resistors connected in series, wherein the first initial voltage is input to a first terminal of the plurality of second resistors; and another terminal of the plurality of second resistors is grounded, wherein the reference voltage is a voltage between two of the plurality of second resistors.

In the above solution, the voltage generator comprises a clock drive sub-circuit and a negative charge pump sub-circuit, wherein the clock drive sub-circuit is configured to receive the first control signal, and generate a fourth control signal according to the first control signal; and the negative charge pump sub-circuit is coupled with the clock drive sub-circuit, and is configured to receive the fourth control signal and output the first voltage according to the fourth control signal.

In the above solution, the negative charge pump sub-circuit comprises at least two negative charge pumps, wherein two adjacent ones of the at least two negative charge pumps are connected in series or in parallel.

In the above solution, the first power supply circuit further comprises a voltage regulator configured to receive a regulation control signal; and regulate the first voltage to a set target voltage value in response to the regulation control signal.

In the above solution, the regulation control signal comprises at least one sub-control signal; the set target voltage value comprises at least one sub-target voltage value; and the voltage regulator comprises at least one group of a P-type transistor and an N-type transistor. In each group, a second initial voltage is input to a first terminal of the P-type transistor, and a second terminal of the P-type transistor is connected with a first terminal of the N-type transistor; and the first voltage is input to a second terminal of the N-type transistor. In each group, a third enable signal is input to a control terminal of the P-type transistor, and a corresponding sub-control signal is input to a control terminal of the N-type transistor, to regulate the first voltage to a corresponding sub-target voltage value of a corresponding group.

In the above solution, the first power supply circuit further comprises at least one second comparator; each second comparator is configured to compare the reference voltage with a corresponding second feedback voltage, and output a corresponding sub-control signal; and the second feedback voltage is a voltage between two of a plurality of first resistors connected in series, and is different from the first feedback voltage.

In the above solution, the peripheral circuit further comprises a third comparator configured to: compare the reference voltage with a third feedback voltage, output the second enable signal according to a comparison result, and output a second enable signal to the second power supply circuit, wherein the third feedback voltage is obtained when a voltage value of the first voltage reaches a preset voltage value.

In the above solution, an absolute value of the first target voltage value of the first voltage is greater than an absolute value of the second target voltage value of the second voltage.

In the above solution, the peripheral circuit further comprises a fourth power supply circuit configured such that: before the first time instant, a bit line voltage reaching a fourth target voltage value is generated to provide the bit line voltage to a corresponding bit line.

In a second aspect, examples of the present application provide a power supply method for a memory device, comprising: starting generating a first voltage at a first time instant, and providing the first voltage to a substrate of a first transistor that is comprised in a first word line drive circuit coupled to a first unselected word line; and starting generating a second voltage at a second time instant, and providing the second voltage to a terminal of the first transistor, wherein the first time instant is earlier than the second time instant.

In the above solution, the second voltage is provided to a source terminal of the first transistor.

In the above solution, the method further comprises: starting generating the first voltage in response to a first enable signal at the first time instant; after a first duration, a voltage value of the first voltage reaches a preset voltage value; and then after a second duration, the voltage value of the first voltage reaches a first target voltage value, wherein a ratio of the preset voltage value to the first target voltage value is between 50% and 90%.

In the above solution, the method further comprises: starting generating the second voltage in response to a second enable signal at the second time instant; and after a third duration, a voltage value of the second voltage reaches a second target voltage value, wherein the second time instant corresponds to a time instant at which the voltage value of the first voltage ramps to the preset voltage value.

In the above solution, the method further comprises: providing the first voltage to a substrate of a second transistor that is comprised in a memory cell comprised in the memory device.

In the above solution, the first voltage and the second voltage are negative voltages, and an absolute value of the first target voltage value of the first voltage is greater than an absolute value of the second target voltage value of the second voltage.

In the above solution, the method further comprises: providing the first voltage to a substrate of a third transistor that is comprised in a second word line drive circuit coupled to a second unselected word line at the first time instant; and starting generating a third voltage at a third time instant, and providing the third voltage to a source terminal of the third transistor, wherein the first time instant is earlier than the third time instant. The third voltage is a negative voltage, and an absolute value of a third target voltage value of the third voltage is greater than a second target voltage value of the second voltage.

In the above solution, the memory device comprises a plurality of memory blocks, and each of the plurality of memory blocks comprises a plurality of rows of memory cells and a word line coupled to each of the plurality of rows of memory cells, wherein the second unselected word line comprises a word line belonging to the same memory block as a selected word line.

In the above solution, the second unselected word line further comprises at least part of word lines that are comprised in a memory block adjacent to a memory block in which the selected word line is located.

In the above solution, the first unselected word line comprises an unselected word line other than the second unselected word line.

In the above solution, generating the first voltage comprises: comparing a reference voltage with a first feedback voltage, and generating a first control signal according to a comparison result; and generating the first voltage according to the first control signal, wherein the first feedback voltage is a feedback voltage obtained according to the first voltage.

In the above solution, the method further comprises: receiving a regulation control signal; and regulating the first voltage to a set target voltage value in response to the regulation control signal, wherein the regulation control signal is obtained according to a comparison result between the reference voltage and a second feedback voltage; and the second feedback voltage is obtained according to the first voltage, and is different from the first feedback voltage.

In the above solution, the method further comprises: comparing a reference voltage with a third feedback voltage, and outputting the second enable signal according to a comparison result, wherein the third feedback voltage is obtained when the voltage value of the first voltage reaches the preset voltage value.

In the above solution, the method further comprises: before the first time instant, generating a bit line voltage reaching a fourth target voltage value to provide the bit line voltage to a corresponding bit line.

In a third aspect, examples of the present application further provide a charge pump circuit for a memory device, comprising: a feedback generator, a reference generator, a first comparator, and a voltage generator, wherein the feedback generator is connected between a first node and an output terminal of the voltage generator and has an input terminal to which a first enable signal is input, and an output terminal of the feedback generator is connected with a first input terminal of the first comparator; the reference generator is connected between the first node and ground, and an output terminal of the reference generator is connected with a second input terminal of the first comparator; an output terminal of the first comparator is connected with an input terminal of the voltage generator; and the output terminal of the voltage generator outputs a negative voltage.

In the above solution, the feedback generator comprises: a fourth transistor, and a plurality of first resistors connected in series, wherein a first terminal of the fourth transistor is connected with the output terminal of the voltage generator, and a second terminal of the fourth transistor is connected with a first terminal of the plurality of first resistors connected in series; the fourth transistor further has a control terminal to which the first enable signal is input; a second terminal of the plurality of first resistors connected in series is connected to the first node; and an output terminal led out between two of the plurality of first resistors connected in series is connected with the first input terminal of the first comparator.

In the above solution, the feedback generator further comprises a fifth transistor and a sixth transistor, wherein a first terminal of the fifth transistor is connected to the first node, and a second terminal of the fifth transistor is connected with the second terminal of the plurality of first resistors connected in series; the fifth transistor further has a control terminal to which a second control signal is input; a first terminal of the sixth transistor is connected to a second node, and a second terminal of the sixth transistor is connected with the second terminal of the plurality of first resistors connected in series; and the sixth transistor further has a control terminal to which a third control signal is input.

In the above solution, the reference generator comprises a plurality of second resistors connected in series, wherein a first terminal of the plurality of second resistors is connected with the second terminal of the fifth transistor and the second terminal of the sixth transistor; a second terminal of the plurality of second resistors is grounded; and an output terminal led out between two of the plurality of second resistors is connected with the second input terminal of the first comparator.

In the above solution, the charge pump circuit further comprises a voltage regulator, wherein the voltage regulator comprises at least one group of a P-type transistor and an N-type transistor. In each group, a first terminal of the P-type transistor is connected to a third node, and a second terminal of the P-type transistor is connected with a first terminal of the N-type transistor; the P-type transistor further has a control terminal to which a third enable signal is input; a second terminal of the N-type transistor is connected with the output terminal of the voltage generator; and the N-type transistor further has a control terminal to which a corresponding sub-control signal is input.

In the above solution, the charge pump circuit further comprises at least one second comparator, wherein a first input terminal of each second comparator is connected with an output terminal of the feedback generator, and a second input terminal of each second comparator is connected with the output terminal of the reference generator; and an output terminal of each second comparator is connected with the control terminal of the N-type transistor of a corresponding group.

In the above solution, the charge pump circuit further comprises a third comparator, wherein a first input terminal of the third comparator is connected with a first output terminal of the feedback generator; a second input terminal of the third comparator is connected with the output terminal of the reference generator; an output terminal of the second comparator outputs a second enable signal, wherein a voltage output by the first output terminal has a preset voltage value, and the second enable signal is configured to enable other charge pump circuits.

In the above solution, the voltage generator comprises a clock drive sub-circuit and a negative charge pump sub-circuit, wherein an input terminal of the clock drive sub-circuit is connected with the output terminal of the first comparator; an output terminal of the clock drive sub-circuit is coupled with an input terminal of the negative charge pump sub-circuit; and an output terminal of the negative charge pump sub-circuit outputs the negative voltage.

In the above solution, the negative charge pump sub-circuit comprises at least two negative charge pumps, wherein two adjacent ones of the at least two negative charge pumps are connected in series or in parallel.

In a fourth aspect, examples of the present application further provide a memory system comprising: at least one memory device, and a memory controller coupled with the memory device and controlling the memory device.

In a fifth aspect, examples of the present application further provide a computer system comprising: the above-mentioned memory system, and a graphic processing unit coupled with the memory system and controlling the memory system.

Examples of the present application provide a memory device, a power supply method, a charge pump circuit, and a system. The memory device comprises: a memory cell array comprising a plurality of rows of memory cells and a word line coupled to each row of memory cells, and a peripheral circuit coupled with a corresponding row of memory cells via the word line and comprising a first power supply circuit and a second power supply circuit, wherein the first power supply circuit is configured to start outputting a first voltage to a substrate of a first transistor that is comprised in a first word line drive circuit coupled to a first unselected word line at a first time instant; and the second power supply circuit is configured to start outputting a second voltage to a terminal of the first transistor at a second time instant, wherein the first time instant is earlier than the second time instant. According to the memory device provided by the examples of the present application, voltages are started to be respectively provided to a substrate and a terminal of the transistor that is comprised in the word line drive circuit at different time instants, so that a coupling effect between the substrate and the terminal of the transistor generated during a power-on process is weakened, thereby effectively suppressing an overshoot generated during the power-on process.

### BRIEF DESCRIPTION OF THE DRAWINGS

In the drawings not necessarily drawn to scale, like numerals may describe like components in different views. Like numerals having different letter suffixes may represent different examples of like components. The drawings generally illustrate various examples discussed in the present disclosure by way of example, but not by way of limitation.

FIG. 1 is a schematic structural diagram of a memory device provided by examples of the present application;

FIG. 2 is a schematic layout diagram I of a memory cell array and a peripheral circuit provided by examples of the present application;

FIG. 3 is a top layout view I of a memory cell array and a peripheral circuit provided by examples of the present application;

FIG. 4 is a schematic layout diagram II of a memory cell array and a peripheral circuit provided by examples of the present application;

FIG. 5 is a top layout view II of a memory cell array and a peripheral circuit provided by examples of the present application;

FIG. 6 is a schematic structural diagram I of a memory device provided by examples of the present application;

FIG. 7 is a schematic diagram of a connection relationship between a memory cell and a word line drive circuit provided by examples of the present application;

FIG. 8 is a timing diagram between a first voltage, a second voltage, and a third voltage provided by examples of the present application;

FIG. 9 is a schematic structural diagram II of a memory device provided by examples of the present application;

FIG. 10 is a schematic layout diagram of blocks in one bank provided by examples of the present application;

FIG. 11 is a schematic structural diagram I of a first power supply circuit provided by examples of the present application;

FIG. 12 is a schematic structural diagram of a voltage generator provided by examples of the present application;

FIG. 13 is an example schematic diagram of the control between negative charge pumps provided by examples of the present application;

FIG. 14 is a schematic structural diagram II of a first power supply circuit provided by examples of the present application;

FIG. 15 is a schematic structural diagram of a voltage regulator comprising three groups of a P-type transistor and an N-type transistor provided by examples of the present application;

FIG. 16 is a schematic structural diagram of a voltage regulator comprising one group of a P-type transistor and an N-type transistor provided by examples of the present application;

FIG. 17 is a schematic structural diagram of a group of second comparators provided by examples of the present application;

FIG. 18 is a schematic structural diagram of a third comparator provided by examples of the present application;

FIG. 19 is a schematic structural diagram III of a memory device provided by examples of the present application;

FIG. 20 is a flow diagram of a power supply method for a memory device provided by examples of the present application;

FIG. 21 is an example schematic structural diagram of a charge pump circuit provided by examples of the present application;

FIG. 22 is a schematic structural block diagram of an electronic apparatus provided by examples of the present application;

FIG. 23 is a schematic structural block diagram of an example solid state drive (SSD) or a universal flash storage (UFS) provided by examples of the present application;

FIG. 24 is a schematic structural block diagram of an example internal memory provided by examples of the present application; and

FIG. 25 is an example schematic diagram of a computer system provided by examples of the present application.

### DETAILED DESCRIPTION

Example implementations disclosed by the present application will be described below in more detail with reference to the drawings. Although example implementations of the present application are shown in the drawings, it is to be understood that, the present application may be implemented in various forms without being limited by the specific implementations as set forth herein. On the contrary, these implementations are provided for a more thorough understanding of the present application, and to fully convey a scope disclosed in the examples of the present application to a person skilled in the art.

In the following descriptions, numerous specific details are given in order to provide a more thorough understanding of the present application. However, it is apparent to those skilled in the art that the present application may be implemented without one or more of these details. In other examples, in order to avoid confusion with the present application, some technical features well-known in the art are not described. That is, all the features of actual examples are not described herein, and well-known functions and structures are not described in detail.

In the drawings, the sizes of a layer, a region, and an element and their relative sizes may be exaggerated for clarity. Like reference numerals denote like elements throughout the specification.

It is to be understood that when an element or a layer is referred to as being “on”, “adjacent to”, “connected to”, or “coupled to” other elements or layers, it may be directly on, adjacent to, connected to, or coupled to the other elements or layers, or intervening elements or layers may be present. In contrast, when an element is referred to as being “directly on”, “immediately adjacent to”, “directly connected to”, or “directly coupled to” other elements or layers, no intervening elements or layers are present. It is to be understood that, although terms first, second, third and the like may be used to describe various elements, components, regions, layers and/or sections, these elements, components, regions, layers and/or sections should not be limited by these terms. These terms are merely used to distinguish one element, component, area, layer or portion from another element, component, area, layer or portion. Therefore, without departing from the teaching of the present application, a first element, component, area, layer, or portion discussed below may be represented as a second element, component, area, layer, or portion. When the second element, component, area, layer, or portion is discussed, it does not mean that the first element, component, area, layer, or portion is necessarily present in the present application.

Spatial relationship terms, such as “beneath”, “below”, “lower”, “under”, “above”, “upper” and the like, may be used here for describing a relationship between one element or feature and other elements or features shown in the drawings. It should be understood that in addition to orientations shown in the drawings, the spatial relationship terms are intended to further include the different orientations of a device in use and operation. For example, if the device in the drawings is turned over, then the elements or the features described as “below” or “under” or “beneath” other elements may be oriented “on” the other elements or features. Therefore, the example terms “below” and “beneath” may comprise both upper and lower orientations. The device may be otherwise oriented (rotated by 90 degrees or other orientations), and the spatial descriptions used here are interpreted accordingly.

The terms used here is merely for the purpose of describing the examples and not as a limitation to the present application. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, a term “and/or” comprises any and all combinations of related items listed.

In order to understand the features and technical contents of the examples of the present application in more detail, the implementation of the examples of the present application are described in detail below with reference to the drawings, which are for reference only and are not intended to limit the examples of the present application.

A DRAM is a semiconductor memory device arranged as a memory cell array via memory cells each consisting of one capacitor and one transistor. The DRAM mainly utilizes the number of charges stored in the capacitor to represent whether one binary bit is 1 or 0. So- called dynamic is relative to static in an SRAM. For the DRAM, due to electrical leakage of the capacitor, the charge will be lost after a period of time, resulting in loss of data due to an insufficient potential. Therefore, it is necessary to perform charging frequently to maintain the potential. This charging operation is called self-refresh. This self-refresh operation needs to persist all the way until data is changed or power is off. Therefore, the DRAM has power-off volatility.

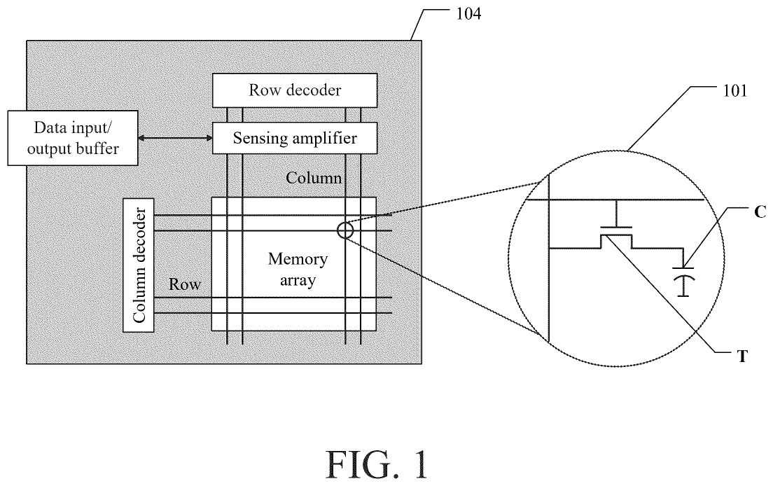

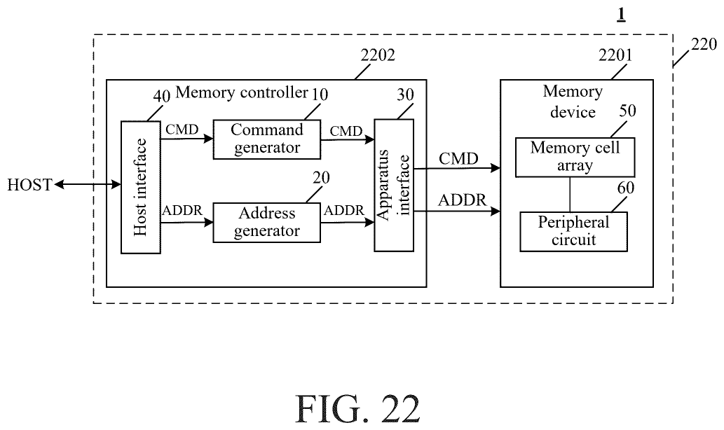

For an understanding of the DRAM, in an example, as shown in FIG. 1, it shows a schematic diagram of an example memory device DRAM according to an example of the present application. The right portion of FIG. 1 shows a circuit of a memory cell in the DRAM. Each DRAM die 104 comprises a memory cell array. The memory cell array comprises a plurality of memory cells 101 that are arranged in an array. Each memory cell 101 comprises one transistor T and one capacitor C. The main operation principle of the memory cell is to utilize the number of charges stored in the capacitor to represent whether one binary bit is 1 or 0. The memory cells are arranged in an array, which may be considered as a typical mesh structure. The memory cell array employs a row and a column to designate an address. By designating an intersection of a row and a column (by designating a row address and a column address of the DRAM), an internal memory controller (such as a memory controller described in the following FIG. 22) may independently access various memory cells in the DRAM die, and perform operations of read or write on the data stored therein.

In some examples, the memory device may comprise a memory cell array and a peripheral circuit. The memory cell array may comprise a plurality of memory banks. Each memory bank may be divided into a plurality of memory blocks, or may be referred to as a memory bank. Each memory block comprises a plurality of rows of memory cells and a plurality of columns of memory cells. Each row of memory cells is coupled with one corresponding word line, and each column of memory cells is coupled with one corresponding bit line. The peripheral circuit may comprise a series of complementary metal-oxide-semiconductor (CMOS) control circuits. For example, this series of CMOS control circuits include: a control circuit corresponding to each memory block, e.g., a sensing amplifier (SA), a word line driver (WLD), etc.; a control circuit corresponding to each memory bank, e.g., a row decoder, a column decoder, etc.; and a control circuit corresponding to all the memory banks, e.g., a command buffer, a command decoder, an address buffer, a data buffer, a mode register, etc.

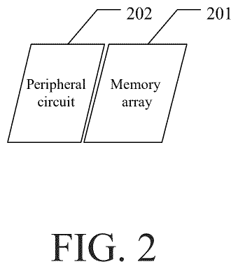

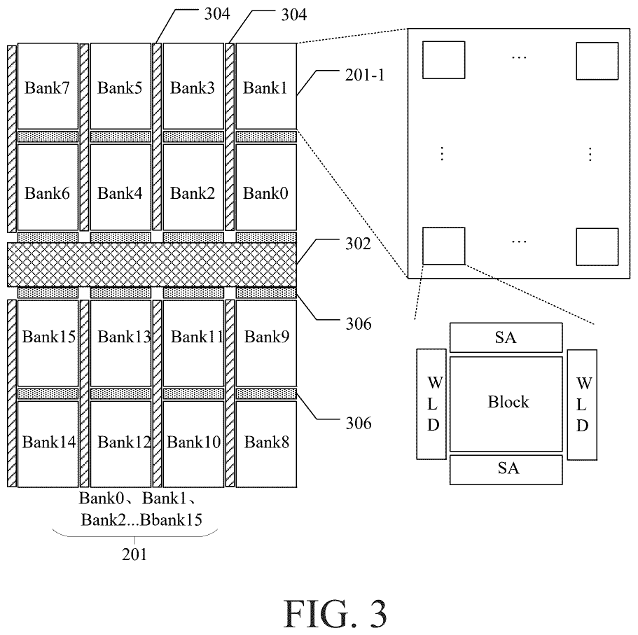

In actual application, for a layout between the memory cell array and the peripheral circuit, in some examples, the memory cell array and the peripheral circuit are disposed on the same substrate in juxtaposition. In an example, FIG. 2 illustrates a schematic layout diagram I of a memory cell array and a peripheral circuit in an example memory, and FIG. 3 illustrates a top layout view I of a memory cell array and a peripheral circuit in an example memory. As shown in FIG. 2, a memory cell array 201 and a peripheral circuit 202 are disposed in juxtaposition. In an example, the memory cell array comprises M memory banks. Each memory bank comprises N memory blocks. A control circuit corresponding to the memory block is disposed on at least one side of each memory block, and a control circuit corresponding to the memory bank is disposed on at least one side of each memory bank. Every K memory banks of the M memory banks form a row of memory banks, and the M memory banks form M/K rows of memory banks. A peripheral circuit corresponding to all the memory banks is disposed between two intermediate rows of memory banks. It is to be noted that M, N, and K here are all positive integers, and M is an integer multiple of K.

For example, as shown in FIG. 3, the memory cell array 201 comprises 16 memory banks 201-1. Each memory bank comprises a plurality of memory blocks. An SA and a WLD that correspond to the memory block are oppositely disposed around each memory block. A column decoder 304 and a row decoder 306 that correspond to the memory bank are disposed on two sides of each memory bank. Every 4 memory banks form one row of memory banks, and 16 memory banks form 4 rows of memory banks. A control circuit 302 is disposed between two intermediate rows of memory banks. It is to be noted that the number of memory banks in FIG. 3 is merely an example, and is not intended to limit the number of memory banks in the memory device in the present application.

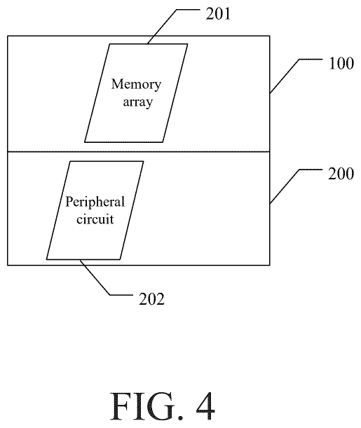

In some examples, the memory cell array 201 and the peripheral circuit 202 may be also disposed on two substrates. As shown in FIG. 4, an example memory comprises: a first substrate 100 at least comprising the memory cell array 201; and a second substrate 200 at least comprising the peripheral circuit 202, wherein the first substrate 100 and the second substrate 200 are stacked, and are connected by bonding.

Here, the first substrate 100 may include, but is not limited to, a silicon substrate. The first substrate 100 may at least comprise the memory cell array 201. In the following, the first substrate 100 may further comprise a dummy memory cell array. The memory cell array 201 may comprise a plurality of memory banks. The plurality of memory banks are arranged in an array. Each memory bank comprises a plurality of memory blocks, or is referred to as a memory bank. The plurality of memory blocks are arranged in an array. Each memory block comprises a plurality of rows of memory cells and a plurality of columns of memory cells. Each row of memory cells and each column of memory cells both comprise a plurality of memory cells. The memory cell array 201 may further comprise a plurality of word lines and a plurality of bit lines. Each row of memory cells is coupled with one corresponding word line, and each column of memory cells is coupled with one corresponding bit line.

Here, the second substrate 200 and the first substrate 100 are different substrates. The second substrate 200 includes, but is not limited to, a silicon substrate. In the following, the second substrate 200 may comprise the peripheral circuit 202. The peripheral circuit 202 may comprise a control circuit corresponding to the memory block and/or a control circuit corresponding to the memory bank. Here, the peripheral circuit 202 further comprises a control circuit corresponding to all the memory banks, for example, a command buffer, a command decoder, an address buffer, a data buffer, a mode register, etc.

In some examples, the memory as shown in FIG. 4 may further comprise: a bonding interface located between the first substrate and the second substrate; a first interconnect layer located between the first substrate and the bonding interface; and a second interconnect layer located between the second substrate and the bonding interface, wherein the first substrate and the second substrate are connected through the first interconnect layer, the bonding interface and the second interconnect layer.

Here, the memory device may further comprise the bonding interface, the first interconnect layer and the second interconnect layer. Both the first interconnect layer and the second interconnect layer may comprise a plurality of bonding contacts and a dielectric that electrically isolates the bonding contacts. In some examples, the bonding contact may comprise a conductive material, including, but not limited to, tungsten (W), cobalt (Co), copper (Cu), aluminum (Al), a silicide, or any combination thereof. The dielectric may include, but is not limited to, silicon oxide, silicon nitride, silicon oxynitride, a low-k (a dielectric constant less than 3.9) dielectric, or any combination thereof. In some examples, the first interconnect layer is formed on the first substrate; the second interconnect layer is formed on the second substrate; and then, the memory cell array comprised in the first substrate and the peripheral circuit comprised in the second substrate are bonded at the bonding interface. The bonding contact and the surrounding dielectric may be connected using hybrid bonding. That is to say, in some examples, the bonding interface is vertically formed between the first interconnect layer and the second interconnect layer. In some examples, the memory cell array in the first substrate and the peripheral circuit in the second substrate are bonded at the bonding interface through the bonding contact comprised in the first interconnect layer and the bonding contact comprised in the second interconnect layer, so as to achieve connection between the memory cell array and the peripheral circuit.

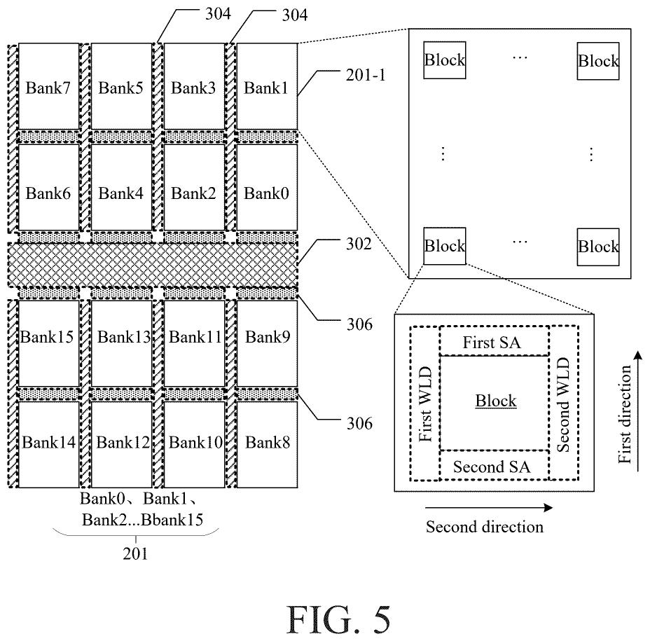

In an example, FIG. 5 illustrates a top layout view II of a memory cell array and a peripheral circuit in a memory. It is to be noted that the first substrate 100 is located above the second substrate 200 in FIG. 5. In FIG. 5, a structure corresponding to a solid line is a structure located in the first substrate 100, and a structure corresponding to a dashed line is a structure located in the second substrate 200. For ease of understanding, the view of the structure in the second substrate 200 is a perspective view.

For example, as shown in FIG. 5, the memory cell array 201 comprises 16 memory banks 201-1. Each memory bank comprises a plurality of memory blocks. A first SA and a second SA that correspond to the memory block and that are oppositely disposed along a first direction, and a first WLD and a second WLD that correspond to the memory block and that are oppositely disposed along a second direction, are disposed right below each memory block. The column decoder 304 and the row decoder 306 that correspond to the memory bank are disposed below two sides of each memory bank. Every 4 memory banks form one row of memory banks, and 16 memory banks form 4 rows of memory banks. The control circuit 302 is disposed below a position between the two intermediate rows of memory banks.

It is to be noted that the number of memory banks in FIG. 5 is merely an example, and is not intended to limit the number of memory banks in the memory in the present application. A space in the first substrate that was used to place the control circuit corresponding to each memory block and the control circuit corresponding to each memory bank can be reserved, so as to provide a larger space for arrangement of the memory cell, the word line, and the bit line.

It is to be noted that a relative size relationship between the size of one memory block and the sizes of a surrounding SA and a word line driver in FIG. 5 is merely an example, and is not intended to limit a relative size relationship between the size of one memory block in the memory and the sizes of one programming logic sub-unit, a surrounding SA, and a word line driver in the present application.

It is to be noted that the above description is merely two example layouts of the memory cell array and the peripheral circuit, and there may be other layouts as well in practice. The focus of this application is not on the layout of the memory cell array and the peripheral circuit, and other layouts will not be repeated here. The operation method provided in the examples of the present application are applicable to various layouts of the memory cell array and the peripheral circuit.

In actual application, during a power-on process for performing read, write, and refresh operations on, for example, the aforementioned memory device, due to the coupling effect, a large voltage overshoot occurs between a word line coupled to an unselected memory cell and a bit line, and between a substrate and a source terminal of a transistor comprised in the word line drive circuit.

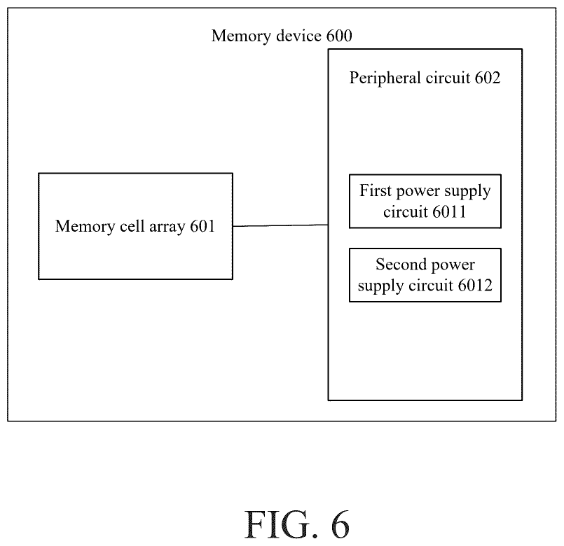

In order to solve one or more of the above technical problems, as shown in FIG. 6, examples of the present application provide a memory device 600 comprising: a memory cell array 601, wherein the memory cell array 601 comprises a plurality of rows of memory cells and a word line coupled to each row of memory cells; and a peripheral circuit 602, wherein the peripheral circuit 602 is coupled with a corresponding row of memory cells via the word line, and comprises a first power supply circuit 6011 and a second power supply circuit 6012.

The first power supply circuit 6011 may be configured to start outputting a first voltage to a substrate of a first transistor that is comprised in a first word line drive circuit coupled to a first unselected word line at a first time instant; and the second power supply circuit 6012 may be configured to start outputting a second voltage to a terminal of the first transistor at a second time instant, wherein the first time instant is earlier than the second time instant.

The first voltage and the second voltage are negative voltages.

The second voltage is provided to a source terminal of the first transistor.

It is to be noted that the memory cell array 601 and the peripheral circuit 602 described here may be understood with reference to the structure described in FIGS. 1 to 5 above. In the examples of the present application, some circuits in the peripheral circuit are modified, and the specific modifications will be described in detail below in conjunction with the drawings.

In an example, the peripheral circuit 602 comprises a first power supply circuit 6011 and a second power supply circuit 6012. Here, the first power supply circuit and the second power supply circuit may be negative charge pump circuits, and specific structures will be described in detail below. The first word line drive circuit may be a drive circuit for driving the first unselected word line. The first power supply circuit provides a voltage to the substrate of the first transistor that is comprised in the first word line drive circuit, and the second power supply circuit provides a voltage to a terminal (such as the source terminal) of the first transistor. Here, the first unselected word line is a word line to which the unselected memory cell is coupled, and is merely an example. Unless otherwise specified, operations of the remaining unselected word lines may be referred to the operation of the first unselected word line. The so-called unselected memory cell may refer to a memory cell that is prohibited from being operated, for example, a memory cell to which data is prohibited from being written, for another example, a memory cell that is prohibited from being read, and for yet another example, a memory cell that is prohibited from being refreshed. That is to say, during the read, write, and refresh operations, etc. of the memory device, negative voltages are provided to a substrate and a terminal (e.g., the source terminal) of the transistor in the drive circuit corresponding to an unselected word line coupled to the unselected memory cell comprised in the memory cell array, so as to prohibit from being operated.

In order to reduce the coupling effect of the substrate and the source terminal of the related transistor, in the examples of the present application, at the first time instant, the first voltage (i.e., the negative voltage), i.e., VBB, is started to be output to the substrate of the first transistor; and then, at a second time instant, the second voltage (i.e., the negative voltage), i.e., VWLN, is started to be output to the source terminal of the first transistor. Here, the first time instant may be earlier than the second time instant, and voltage values of both the first voltage and the second voltage increase over time until a corresponding target voltage value is reached.

In some examples, the plurality of rows of memory cells may comprise a plurality of memory cells. The memory cell may comprise a second transistor and a capacitor, wherein a first terminal of the second transistor is connected with a terminal of the capacitor, a second terminal of the second transistor is connected with a bit line corresponding to the second transistor, and a control terminal of the second transistor is connected with a word line corresponding to the second transistor. The first power supply circuit may be further configured to provide the first voltage to a substrate of the second transistor.

It is to be noted that, as shown in FIG. 1, one memory cell comprises one transistor and one capacitor that are arranged in an array. In some examples, the substrate of the second transistor that is comprised in the memory cell and the substrate of the first transistor that is comprised in the word line drive circuit belong to the same substrate. In some other examples, the substrate of the second transistor that is comprised in the memory cell and the substrate of the first transistor that is comprised in the word line drive circuit are connected to the same voltage source. In either way mentioned above, in the examples of the present application, the first voltage provided by the first power supply circuit may be further provided to the substrate of the second transistor that is comprised in the memory cell.

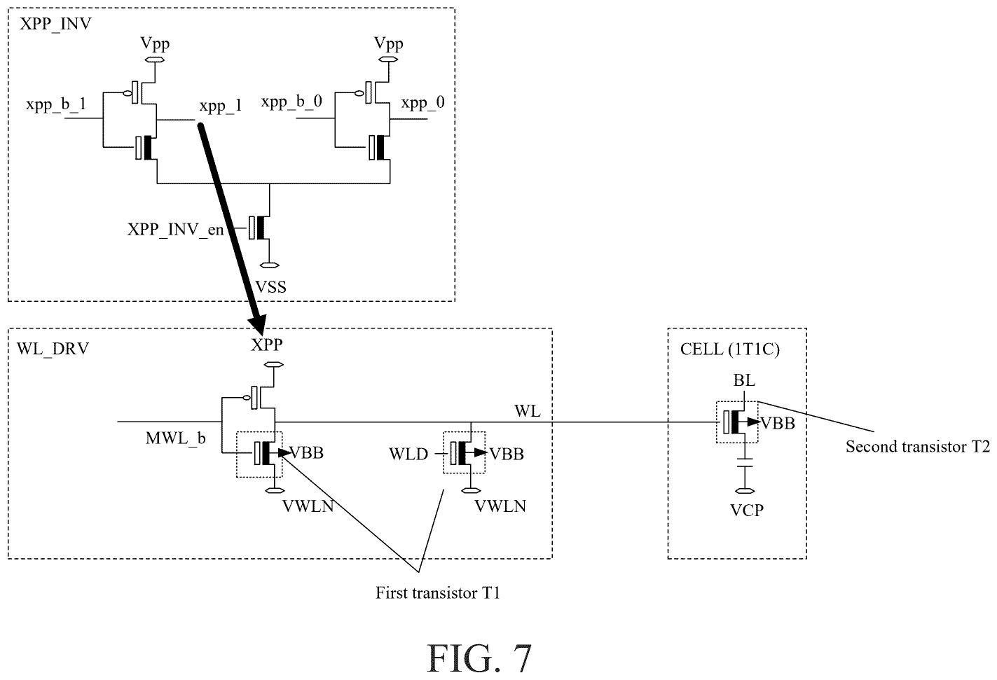

In order to understand the above solution, as shown in FIG. 7, FIG. 7 illustrates a schematic structural diagram of circuit connection between the word line drive circuit and the memory cell provided by examples of the present application. XPP_INV is one power supply circuit for the word line drive circuit. An output terminal xpp_1 or xpp_0 of XPP_INV is connected with an XPP terminal of a word line drive circuit WL_DRV. The word line drive circuit WL_DRV comprises two first transistors T1. CELL is also known as a memory cell. A type of the memory cell in FIG. 7 is a capacitive memory cell. This type of memory cell comprises one second transistor T2 and one capacitor, i.e., 1T1C. In actual use, a node XPP is connected with xpp_1 or xpp_0 of the power supply circuit XPP_INV. When the power supply circuit XPP_INV and the WL_DRV operate, and when each enable signal xpp_b_1 or xpp_b_0 is in an active state (a low level state), XPP_INV_en is in an active state (a high level state), MWL_b is in an active state (a low level state), and WLD is in an inactive state (a low level state), a word line WL is pulled up to Vpp. The above process is a flow process of driving a selected word line. The present application focuses on driving an unselected word line. Unless otherwise specified, described driving processes and operations of applying a voltage and the like are performed on a circuit related to the unselected word line.

Based on this, according to the structure shown in FIG. 7, examples of the present application provide the following solution: at the first time instant, the first power supply circuit starts outputting the first voltage to the substrates of the first transistor and the second transistor, that is, the negative voltage VBB is provided to the substrates of the first transistor and the second transistor; and then, at the second time instant, the second power supply circuit starts outputting the second voltage to the source terminal of the first transistor, that is, the negative voltage VWLN is provided to the source terminal of the first transistor. The first voltage and the second voltage are voltage signals whose voltage values may increase from zero towards a negative direction. The foregoing description is a suppressing operation (or a prohibiting operation) for a memory cell coupled to an unselected word line. That is, first, a voltage value of the VBB ramps towards the negative direction, and a voltage value of the VWLN ramps towards the negative direction. Due to such a design, the coupling effect caused by simultaneous ramping of both the voltage values is weakened, so that overshoot of voltages on the substrate and the source terminal of the transistor are effectively suppressed during the ramping process. In addition, when the negative voltage is applied to the substrate and the source terminal of the first transistor of the first word line drive circuit, and when the power supply circuit XPP_INV of the first word line drive circuit does not operate, a word line voltage of a memory cell coupled with the first unselected word line is a negative voltage, so as to further suppress the memory cell from being operated.

In some examples, the first power supply circuit may be further configured to start outputting the first voltage in response to a first enable signal at the first time instant; after a first duration, a voltage value of the first voltage reaches a preset voltage value; and then after a second duration, the voltage value of the first voltage reaches a first target voltage value.

In some examples, the second power supply circuit may be further configured to start outputting the second voltage in response to a second enable signal at the second time instant; and after a third duration, a voltage value of the second voltage reaches a second target voltage value.

It is to be noted that the first voltage and the second voltage illustrated above may be voltages ramping from zero towards a negative direction over time. Based on this, after the first duration from the first time instant, the voltage value of the first voltage reaches the preset voltage value, and then after the second duration, the voltage value of the first voltage reaches the first target voltage. After the third duration from the second time instant, the voltage value of the second voltage reaches the second target voltage. The first duration, the second duration, and the third duration are respectively determined by the preset voltage value, the first target voltage, and the second target voltage, which is not limited here.

The second time instant corresponds to a time instant at which the voltage value of the first voltage ramps to the preset voltage value.

In some examples, a ratio of the preset voltage value to the first target voltage value is between 50% and 90%.

It is to be noted that the second time instant may correspond to the corresponding time instant at which the voltage value of the first voltage ramps to the preset voltage value, wherein the ratio of the preset voltage value to the first target voltage value of the first voltage is between 50% and 90%. In some examples, the ratio of the preset voltage value to the first target voltage value of the first voltage may be 50%. In some other examples, the ratio of the preset voltage value to the first target voltage value may be 90%. That is to say, the range of the ratio includes the endpoint values on both sides.

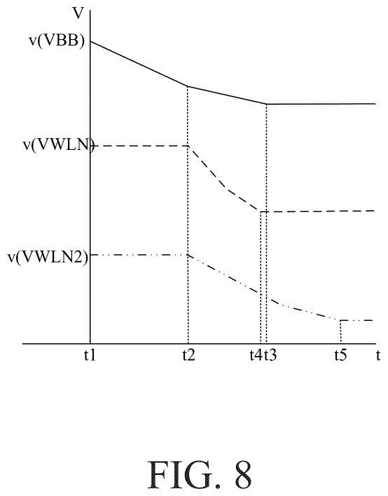

In an example, as shown in FIG. 8, FIG. 8 illustrates a timing diagram of the first voltage, the second voltage, and the third voltage described later. As shown in FIG. 8, for the first voltage, at a time instant t1, the first power supply circuit starts outputting the first voltage, and after the first duration, i.e., at a time instant t2, the voltage value of the first voltage reaches the preset voltage value. At this point, the preset voltage is 70% of the first target voltage; and then after the second duration, i.e., at a time instant t3, the voltage value of the first voltage reaches the first target voltage. It should be understood that, as previously described, the first voltage is a negative voltage. Therefore, the voltage value herein only refers to its magnitude, and does not indicate its direction, similarly hereinafter. Similarly, for the second voltage, the second power supply circuit starts outputting the second voltage from the time instant t2, and after the third duration, i.e., at a time instant t4, the voltage value of the second voltage reaches the second target voltage.

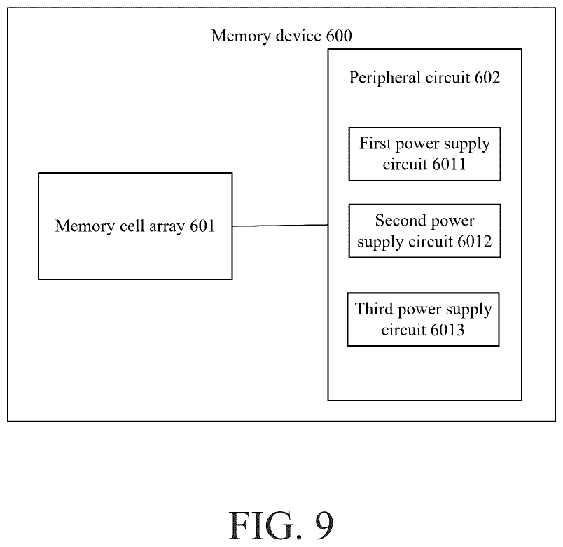

In some examples, as shown in FIG. 9, the peripheral circuit may further comprise a third power supply circuit 6013.

The first power supply circuit 6011 may be further configured to start outputting the first voltage to a substrate of a third transistor that is comprised in a second word line drive circuit coupled to a second unselected word line at the first time instant.

The third power supply circuit 6013 may be configured to start outputting a third voltage to a terminal of the third transistor at a third time instant, wherein the first time instant is earlier than the third time instant.

The third voltage is provided to a source terminal of the third transistor.

The third voltage is a negative voltage, and an absolute value of a third target voltage value of the third voltage is greater than the second target voltage value of the second voltage.

In actual application, unselected rows of memory cells with different distances from a row of memory cells coupled with the selected word line have different impacts on an operation on the selected memory cell. When the unselected row of memory cells is closer to the selected row of memory cells, the impact on the selected row of memory cells is larger. When the unselected row of memory cells is farther away from the selected row of memory cells, the impact on the selected row of memory cells is smaller. Therefore, different negative voltages may be applied to unselected word lines with different distances from the selected word line, and a larger value of negative voltage is applied to the unselected word line that is closer to the selected word line, which can effectively reduce the impact of these unselected word lines on an operation on the selected memory cell coupled to the selected word line. Based on this, in the examples of the present application, at the first time instant, the first power supply circuit starts outputting the first voltage to the substrate of the third transistor that is comprised in the second unselected word line. At the third time instant, the third power supply circuit starts outputting the third voltage to the source terminal of the third transistor, and the first time instant is earlier than the third time instant. The third target voltage value of the third voltage is greater than the second target voltage value of the second voltage.

In some examples, the third time instant and the aforementioned second time instant may be the same time instant.

In some examples, the third time instant and the aforementioned second time instant may not be the same time instant. In an example, because the third target voltage value of the third voltage is greater than the second target voltage value of the second voltage, the third time instant may be earlier than the second time instant in order not to increase the overall operation time.

In actual application, the third time instant may also be later than the second time instant, as long as a time difference between the third time instant and the second time instant has no significant impact on the overall operation time. In an example, a relationship between the third time instant and the second time instant may be determined according to an actual situation, which is not limited here.

In the examples of the present application, two different power supply voltages, namely the second power supply circuit and the third power supply circuit, are adopted as the power supply voltages that generate the second voltage and the third voltage. In the case of actual application, if a power supply technology permits, the second voltage and the third voltage may be obtained separately by controlling a ramp time. That is, the second power supply circuit and the third power supply circuit may be also the same power supply circuit. Here, a relationship between the second power supply circuit and the third power supply circuit may be also selected according to an actual situation, which is not limited here.

Based on this, as shown in FIG. 8, FIG. 8 provides a timing diagram of the second voltage and the third voltage when the second time instant is the same as the third time instant. The foregoing describes a variation in the second voltage over time. For the third voltage, the third power supply circuit starts outputting the third voltage from the time instant t2, and after a fourth duration, i.e., at a time instant t5, the voltage value of the third voltage reaches the third target voltage.

The foregoing describes that different voltages may be applied to a source terminal of a transistor that is comprised in the unselected word line. In some examples, the memory cell array may comprise a plurality of memory blocks. Each memory block comprises the plurality of rows of memory cells and the word line coupled to each of the plurality of rows of memory cells. The second unselected word line comprises a word line belonging to the same memory block as a selected word line.

In some examples, the second unselected word line further comprises at least part of word lines that are comprised in a memory block adjacent to a memory block in which the selected word line is located.

In some examples, the first unselected word line comprises an unselected word line other than the second unselected word line.

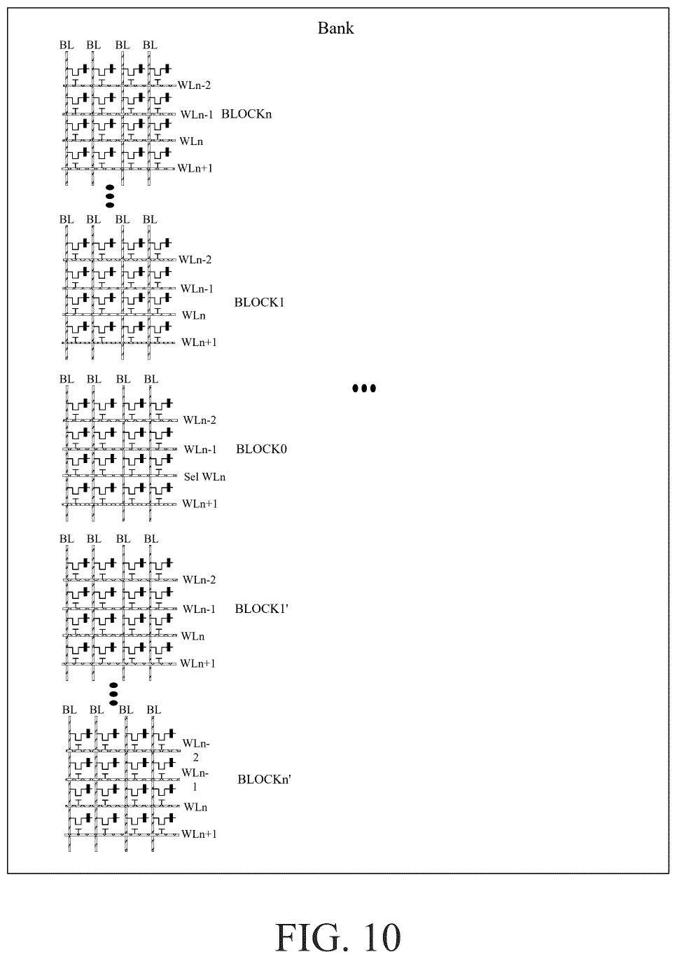

In order to illustrate the case above, in an example, an example structure of the memory cell array is shown in FIG. 3 or 5. The memory cell array comprises a plurality of banks each comprising a plurality of memory blocks. Here, as shown in FIG. 10, FIG. 10 illustrates a schematic structural diagram of a memory block in a column of a bank provided by examples of the present application. sel WLn in Block0 is a selected word line. WLn−1, WLn−2, WLn+1, and the like in Block0 are all unselected word lines, and word lines in the remaining blocks are all unselected word lines. Based on the memory cell array shown in FIG. 10, in the examples of the present application, the second unselected word line may comprise word lines such as WLn−1, WLn−2, WLn+1, and the like in Block0. The second unselected word line may further comprise at least part of word lines in Block1 and Block1′. In an example, the at least part of word lines in Block1 and Block1′ may be all the word lines. Alternatively, the at least part of word lines in Block1 and Block1′ may be a half of word lines in Block1 and of Block1′ that are closer to the selected word line. The so-called first unselected word line may be another unselected word line other than the second unselected word line, for example, all word lines that are outside Block1 and Block1′ until those between Blockn and Blockn′.

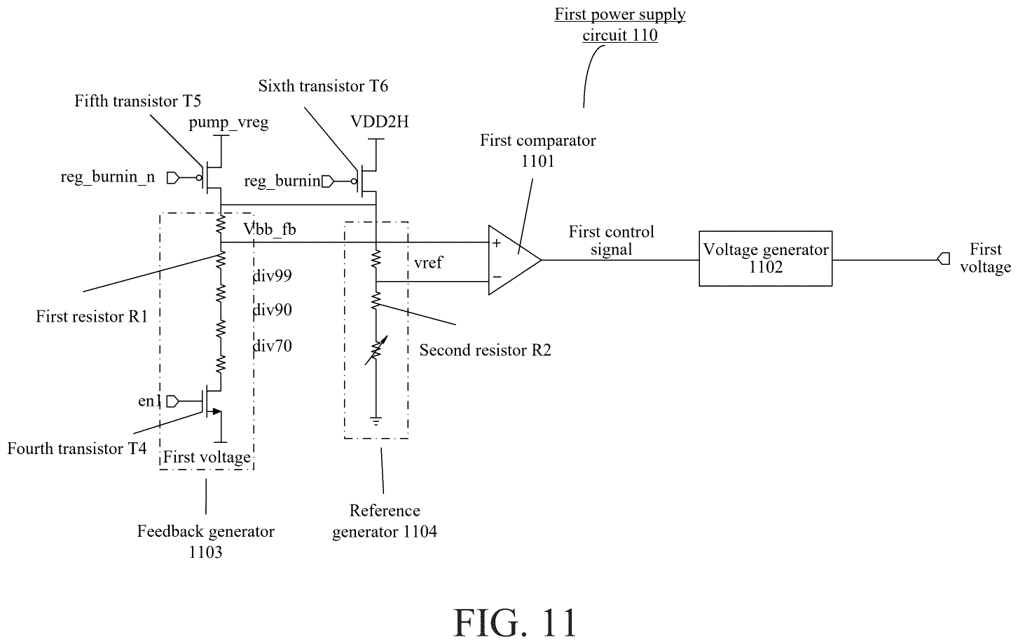

In some examples, as shown in FIG. 11, the first power supply circuit 110 may comprise a first comparator 1101 and a voltage generator 1102, wherein the first comparator 1101 may be configured to compare a reference voltage with a first feedback voltage, and output a first control signal according to a comparison result; and the first feedback voltage is obtained according to the first voltage output by the voltage generator.

The voltage generator 1102 may be configured to output the first voltage according to the first control signal.

It is to be noted that, as previously described, the first power supply circuit may be a negative charge pump circuit with a specific circuit shown in FIG. 11. The first power supply circuit comprises the first comparator 1101 and the voltage generator 1102, wherein the first comparator 1101 receives the reference voltage and the first feedback voltage, and compares the reference voltage with the first feedback voltage to obtain a comparison result; and generates the first control signal according to the comparison result, and transmits the first control signal to the voltage generator. Thereafter, the voltage generator 1102 receives the first control signal, and outputs the first voltage according to the first control signal.

The first feedback voltage is a feedback voltage of the first voltage output by the voltage generator. In some examples, as shown in FIG. 11, the first power supply circuit 110 may further comprise: a feedback generator 1103 configured to receive the first voltage, and output the first feedback voltage according to the first voltage; and a reference generator 1104 configured to output the reference voltage.

That is to say, the first power supply circuit may further comprise a feedback generator that generates the first feedback voltage. In an example, the feedback generator receives the first voltage, and outputs the first feedback voltage according to the first voltage. In some examples, the feedback generator 1103 may comprise: a fourth transistor, and a plurality of first resistors connected in series, wherein the first voltage is input to a first terminal of the fourth transistor, and a second terminal of the fourth transistor is connected with a first terminal of the plurality of first resistors; and a first initial voltage is input to a second terminal of the plurality of first resistors, wherein at the first time instant, a first enable signal is input to a control terminal of the fourth transistor, and the feedback generator outputs the first feedback voltage that is a voltage between two of the plurality of first resistors.

Here, the above-mentioned fourth transistor is a fourth transistor T4 in FIG. 11. The plurality of first resistors connected in series are a plurality of first resistors R1 connected in series as shown in FIG. 11. The first voltage is input to a first terminal (e.g., a drain terminal) of the fourth transistor T4, a second terminal of the fourth transistor T4 is connected with a first terminal of the plurality of first resistors R1, and a first initial voltage pump_vreg is input to a second terminal of the plurality of first resistors. At the first time instant, the first enable signal en1 is input to the control terminal of the fourth transistor T4. A first voltage with a voltage value of 0 is input to the feedback generator, and the feedback generator outputs the first feedback voltage Vbb_fb at the first time instant. Thereafter, the first feedback voltage varies with a variation in the voltage value of the first voltage. The value of the first feedback voltage at the first time instant may be determined as a voltage between which two first resistors according to the first target voltage. In an example, as shown in FIG. 11, the first feedback voltage is a voltage between the uppermost first resistor of the plurality of first resistors and an adjacent first resistor. This may be selected according to an actual situation.

In some examples, the reference generator 1104 may comprise a plurality of second resistors connected in series, wherein the first initial voltage is input to a first terminal of the plurality of second resistors; and another terminal of the plurality of second resistors is grounded, wherein the reference voltage is a voltage between two of the plurality of second resistors.

In an example, as shown in FIG. 11, the reference generator 1104 comprises three second resistors R2, and the reference voltage vref may be a voltage between the uppermost second resistor of the plurality of second resistors and an adjacent second resistor. This may be selected according to an actual situation. In actual application, in order to have a large regulation range for the reference voltage, part of the second resistors may be employed as adjustable resistors. For example, a grounded second resistor shown in FIG. 11 is an adjustable resistor.

In some examples, as shown in FIG. 11, the feedback generator may further comprise a fifth transistor and a sixth transistor, wherein a first sub-voltage comprised in the first initial voltage is input to a first terminal of the fifth transistor, and a second terminal of the fifth transistor is connected with the second terminal of the plurality of first resistors; a second sub-voltage comprised in the first initial voltage is input to a first terminal of the sixth transistor, and a second terminal of the sixth transistor is connected with the second terminal of the plurality of first resistors, wherein a second control signal is input to a control terminal of the fifth transistor, and the first power supply circuit operates in a first mode; and a third control signal is input to a control terminal of the sixth transistor, and the first power supply circuit operates in a second mode.

The first mode is a normal operation mode. That is, the first power supply circuit is in a normal operation mode when the memory device performs the read, write, and refresh operations, etc. The second mode is an aging test mode. That is, the first power supply circuit is in an aging test mode when electrical property tests such as an aging test and the like are performed on devices such as the memory device and the like. In an example, as shown in FIG. 11, when the second control signal reg_burnin_n is input to the control terminal of the fifth transistor T5, the first power supply circuit enters the first mode for operation. When the third control signal reg_burnin is input to the control terminal of the sixth transistor T6, the first power supply circuit enters the second mode for operation. The first initial voltage may be a supply voltage provided, wherein the first sub-voltage may be different from the second sub-voltage. For example, the first sub-voltage may be pump_vreg described above in FIG. 11; and the second sub-voltage may be VDD2H described above in FIG. 11.

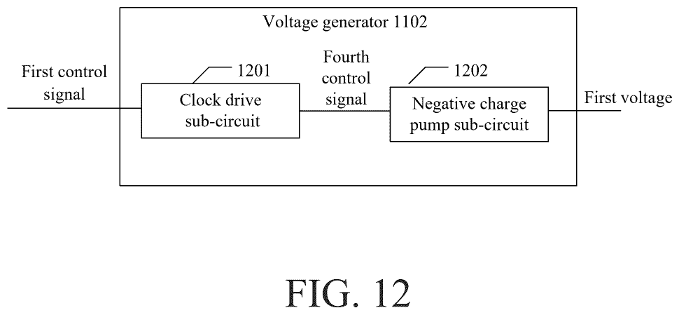

In some examples, as shown in FIG. 12, the voltage generator 1102 may comprise a clock drive sub-circuit 1201 and a negative charge pump sub-circuit 1202, wherein the clock drive sub-circuit 1201 is configured to receive the first control signal, and generate a fourth control signal according to the first control signal; and the negative charge pump sub-circuit 1202 is coupled with the clock drive sub-circuit, and is configured to receive the fourth control signal and output the first voltage according to the fourth control signal.

In some examples, the negative charge pump sub-circuit may comprise at least two negative charge pumps, wherein two adjacent ones of the at least two negative charge pumps are connected in series or in parallel.

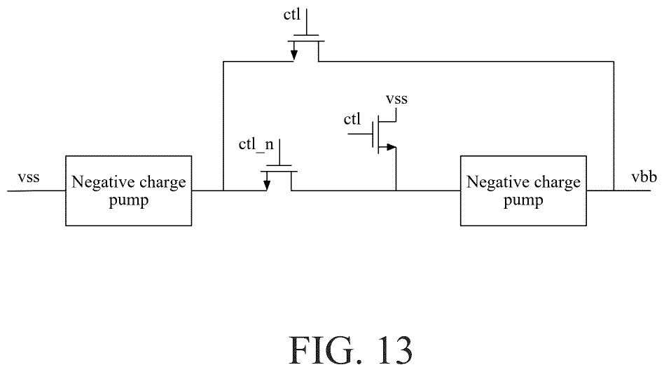

For example, as shown in FIG. 13, the negative charge pump sub-circuit comprises two negative charge pumps that are controlled according to a control signal ctl and an inverse control signal ctl_n. When ctl=1, the two negative charge pumps are connected in parallel, and the negative charge pump sub-circuit is a first level pump circuit. When ctl=0, the two negative charge pumps are connected in series, and the negative charge pump sub-circuit is a second level pump circuit. It should be understood that, in actual use, the negative charge pump sub-circuit may comprise more than two negative charge pumps. Every two adjacent ones of the negative charge pumps may be controlled in the above manner, such that the two adjacent negative charge pumps are connected in series or in parallel.

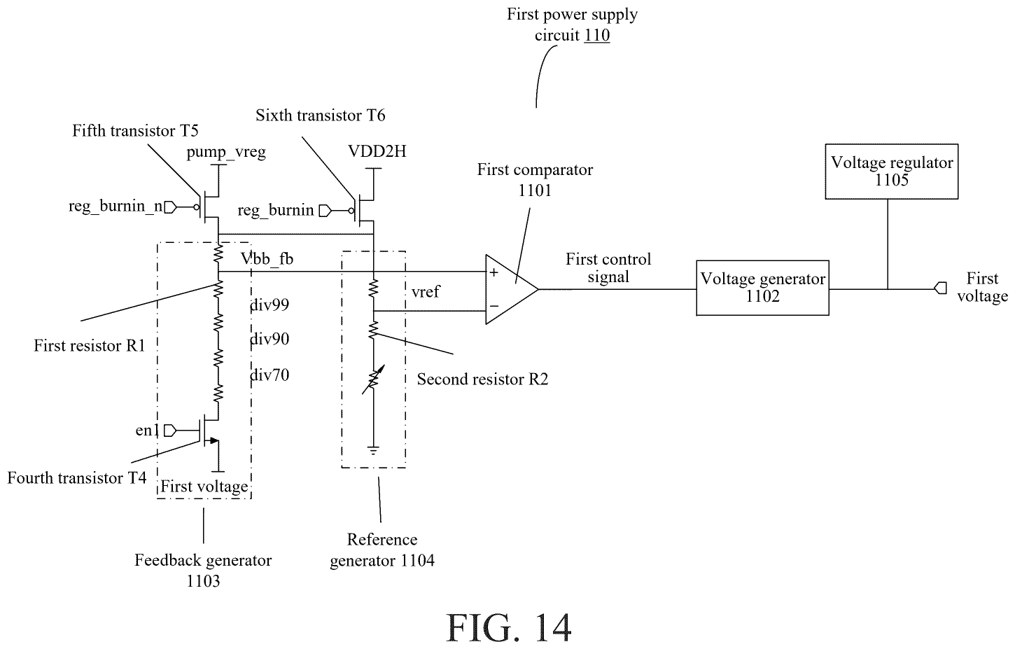

In some examples, as shown in FIG. 14, the first power supply circuit further comprises a voltage regulator 1105 that may be configured to: receive a regulation control signal; and regulate the first voltage to a set target voltage value in response to the regulation control signal.

It is to be noted that the first power supply circuit further comprises a voltage regulator having a pull-up capability, which enables the voltage regulator to regulate the voltage value of the first voltage to the set target voltage value when the voltage value of the first voltage decreases by a certain amount due to the coupling effect. A specific magnitude of the set target voltage value may be selected according to an actual circuit, which is not limited here. In an example, when the voltage of the substrate of the first transistor described above decreases by 50 millivolts (mV) due to the coupling effect, the voltage regulator is enabled to reduce the coupled pull-down. The amount of regulation is selected according to an actual situation. A detailed illustration is made below in conjunction with the drawings.

In some examples, the regulation control signal may comprise at least one sub-control signal. The set target voltage value may comprise at least one sub-target voltage value. The voltage regulator may comprise at least one group of a P-type transistor and an N-type transistor. In each group, a second initial voltage is input to a first terminal of the P-type transistor, and a second terminal of the P-type transistor is connected with a first terminal of the N-type transistor; and the first voltage is input to a second terminal of the N-type transistor. In each group, a third enable signal is input to a control terminal of the P-type transistor, and a corresponding sub-control signal is input to a control terminal of the N-type transistor, so as to regulate the first voltage to a corresponding sub-target voltage value of a corresponding group.

It is to be noted that one sub-control signal corresponds to one sub-target voltage value, and one sub-control signal and one sub-target voltage value correspond to one group of a P- type transistor and an N-type transistor. In each group, a second initial voltage is input to the first terminal of the P-type transistor, and the second terminal of the P-type transistor is connected with the first terminal of the N-type transistor; and the first voltage is input to the second terminal of the N-type transistor. In addition, the third enable signal is input to the control terminal of the P-type transistor, and the corresponding sub-control signal is input to the control terminal of the N-type transistor, so that the regulation is initiated, and the voltage value of the first voltage is regulated to a corresponding sub-target voltage value of a corresponding group. The above-mentioned second initial voltage may be a supply voltage provided, for example, VDD2H.

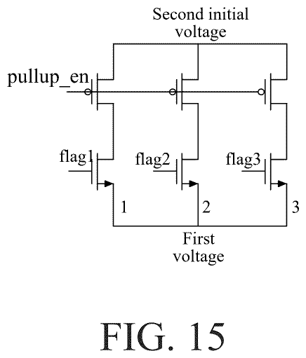

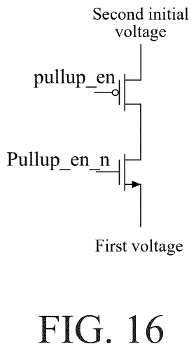

In an example, as shown in FIGS. 15 and 16, FIG. 15 illustrates a schematic structural diagram of the voltage regulator provided by examples of the present application; and FIG. 16 illustrates another schematic structural diagram of the voltage regulator provided by examples of the present application. In FIG. 15, pullup_en is the third enable signal; and flag1, flag2, and flag3 are three sub-control signals. The voltage regulator comprises three groups of a P-type transistor and an N-type transistor, that is, comprises three magnitude levels for regulation. In an example, a group of a P-type transistor and an N-type transistor corresponding to flag1 corresponds to one sub-target voltage value; a group of a P-type transistor and an N-type transistor corresponding to flag2 corresponds to one sub-target voltage value; and a group of a P-type transistor and an N-type transistor corresponding to flag3 corresponds to one sub-target voltage value. The voltage regulator shown in FIG. 16 comprises one group of a P-type transistor and an N-type transistor, that is, comprises one magnitude level for regulation. In addition, a corresponding sub-control signal is an inverse of the third enable signal pullup_en_n.

In some examples, the first power supply circuit may further comprise at least one second comparator. Each second comparator is configured to compare the reference voltage with a corresponding second feedback voltage, and output a corresponding sub-control signal. The second feedback voltage is a voltage between two of the plurality of first resistors connected in series, and is different from the first feedback voltage.

It is to be noted that each second comparator corresponds to a group of a P-type transistor and an N-type transistor comprised in the voltage regulator shown in FIG. 15, and is configured to output a corresponding sub-control signal, that is, one of flag1, flag2, and flag3.

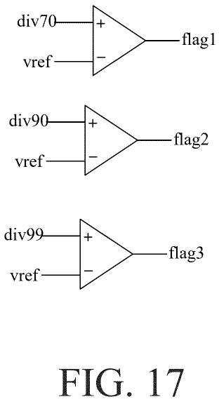

In an example, as shown in FIG. 17, FIG. 17 illustrates a circuit structural diagram for generation of flag1, flag2, and flag3 provided by examples of the present application. In FIG. 17, vref is a reference voltage. div70 is a voltage value of the second feedback voltage corresponding to flag1. div90 is a voltage value of the second feedback voltage corresponding to flag2. div99 is a voltage value of the second feedback voltage corresponding to flag3. The second feedback voltage has a different meaning from that of the first feedback voltage. The second feedback voltage is used to start a certain regulation level of the voltage regulator. The first feedback voltage is related to the first target voltage value of the first voltage, and varies with a variation in an output of the voltage generator. That is to say, the second feedback voltage may be part of the first feedback voltage. That is, the voltage value of the second feedback voltage is equal to part of the voltage value of the first feedback voltage, for example, div70, div90, and div99.

In some examples, the peripheral circuit may further comprise a third comparator configured to: compare the reference voltage with a third feedback voltage, output the second enable signal according to a comparison result, and output the second enable signal to the second power supply circuit, wherein the third feedback voltage is obtained when the voltage value of the first voltage reaches the preset voltage value.

It is to be noted that, as previously described, the second time instant at which the second power supply circuit starts outputting the second voltage may be a corresponding time instant at which the first voltage ramps to the preset voltage value. At this point, a feedback voltage corresponding to the first voltage may be the third feedback voltage. Based on this, the third comparator compares the reference voltage with the third feedback voltage, so as to output the second enable signal.

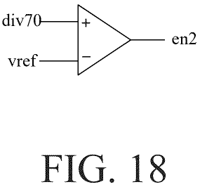

In an example, as shown in FIG. 18, FIG. 18 illustrates a schematic structural diagram of the third comparator provided by examples of the present application. In FIG. 18, en2 is the second enable signal. Here, the third feedback signal is a feedback voltage generated when the voltage value of the first voltage ramps to 70% of the first target voltage. At this point, after comparing the third feedback voltage with the reference voltage, the third comparator outputs the second enable signal en2 to the second power supply circuit. It is to be noted that, in actual application, when the preset voltage value is 70% of the first target voltage, and the voltage regulator employs a regulation circuit of a branch of flag1, one of the second comparator and the third comparator corresponding thereto may be employed. That is, flag1 and the second enable signal en2 may be the same signal, but it may provide control signals to different voltages.

The structure of the first power supply circuit has been introduced above in detail. The structure of the second power supply circuit supplying power to the source of the first transistor and the structure of the third power supply circuit supplying power to the source terminal of the third transistor may be the same as or similar to the structure of the first power supply circuit.

In an example, referring to FIG. 11, the second power supply circuit is illustrated as an example. First, an overall structure of the second power supply circuit is the same as that of the first power supply circuit. The first power supply circuit and the second power supply circuit each comprise a first comparator, a feedback generator, a reference generator, a voltage regulator, and a voltage generator. Differences between the second power supply circuit and the first power supply circuit are that: first, due to different loads, the numbers of negative charge pumps comprised in the negative charge pump sub-circuit in the voltage generator and the serial or parallel connection manners between the negative charge pumps may be different. Second, since the second target voltage value is different from the first target voltage value, the numbers of the first resistors R1 comprised in the feedback generator as shown in FIG. 11 may be different, or output terminals corresponding to Vbb_fb may be different. In an example, as shown in FIG. 11, the feedback voltage Vbb_fb of the example first voltage is a voltage between the two uppermost first resistors R1. If the number of the first resistors R1 in the first power supply circuit is the same as the number of the first resistors R1 in the second power supply circuit, a feedback voltage of the second target voltage value may be a voltage between two other first resistors R1. If the number of the first resistors R1 in the first power supply circuit is different from the number of the first resistors R1 in the second power supply circuit, for example, the feedback voltages of both the first target voltage and the second target voltage may be a voltage between the two uppermost first resistors R1, and the number of the first resistors R1 in the second power supply circuit is greater than the number of the first resistors R1 in the first power supply circuit, for example, as shown in FIG. 11, the number of the first resistors R1 in the first power supply circuit is 5, the number of the first resistors R1 in the second power supply circuit may be 6 or more. Third, enable signals en1 of the fourth transistors T4 are different. In an example, the enable signal of the fourth transistor T4 of the feedback generator in the first power supply circuit is the first enable signal; and the enable signal of the fourth transistor T4 in the second power supply circuit is the second enable signal, i.e., the second enable signal generated when the first voltage ramps to the preset voltage value (e.g., 70% of the first target voltage).

The case of the third power supply circuit is the same as that of the second power supply circuit, and differences of the third power supply circuit from the second power supply circuit and the first power supply circuit are also understood by analogy from the above aspects, which is no longer repeated here for brevity.

In some examples, an absolute value of the first target voltage value of the first voltage is greater than an absolute value of the second target voltage value of the second voltage.

It is to be noted that, as shown in FIG. 7, when a voltage VBB of the substrate of the first transistor T in the word line drive circuit is greater than VWLN, it may result in a relatively large electrical leakage. In addition, because both VBB and VWLN are negative voltages, only if VBB is more negative, a potential of the source terminal of the first transistor T1 is greater than a potential of the substrate of the first transistor T1, that is, a voltage value of VBB is greater than a voltage value of VWLN, that is to say, the absolute value of the first target voltage value of the first voltage is greater than the second target voltage value of the second voltage.

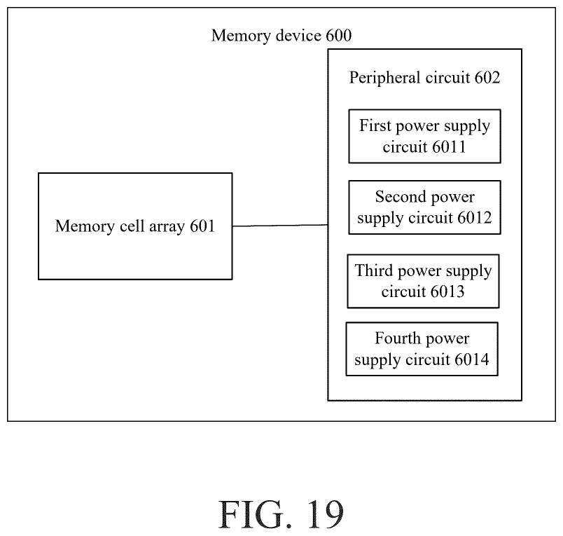

In some examples, as shown in FIG. 19, the peripheral circuit further comprises a fourth power supply circuit 6014 configured such that: before the first time instant, a bit line voltage reaching a fourth target voltage value is generated to provide the bit line voltage to the corresponding bit line.

It is to be noted that, as previously described, the causes of generation of the coupling effect further include the coupling effect generated during a power-on process of the bit line and the word line. Therefore, in order to reduce the coupling effect between the word line and the bit line during the power-on process, the power-on of the corresponding bit line is completed before the first time instant. That is, the fourth power supply circuit is configured such that: before the first time instant, a bit line voltage reaching a fourth target voltage value is generated to provide the bit line voltage to the corresponding bit line.

In the examples of the present application, voltages starting to ramp at different time instants are provided to the source terminal and the substrate of the first transistor that is comprised in the word line drive circuit corresponding to the unselected word line, to reduce the coupling effect between the source terminal and the substrate due to the power-on. In addition, according to different distances from the selected word line, the unselected word line is divided into a first unselected word line and a second unselected word line, such that negative voltages with different voltage values are applied to the source terminals of the first transistors that are comprised in the first unselected word line and the second unselected word line, thereby effectively reducing the impact on an operation of a selected memory cell corresponding to a memory cell that is coupled to the unselected word line close to the selected word line.

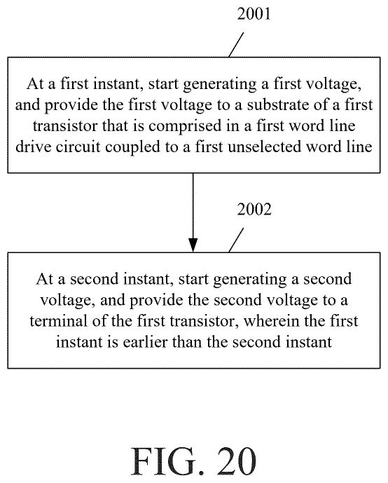

Based on the memory device described above, as shown in FIG. 20, examples of the present application provide a power supply method for a memory device, which may comprise:
operation 2001: starting generating a first voltage at a first time instant, and providing the first voltage to a substrate of a first transistor that is comprised in a first word line drive circuit coupled to a first unselected word line; and
operation 2002: starting generating a second voltage at a second time instant, and providing the second voltage to a terminal of the first transistor,
wherein the first time instant is earlier than the second time instant.

In some examples, the second voltage is provided to a source terminal of the first transistor.

In some examples, the method further comprises: starting generating the first voltage in response to a first enable signal at the first time instant; after a first duration, a voltage value of the first voltage reaches a preset voltage value; and then after a second duration, the voltage value of the first voltage reaches a first target voltage value, wherein a ratio of the preset voltage value to the first target voltage value is between 50% and 90%.

In some examples, the method further comprises: starting generating the second voltage in response to a second enable signal at the second time instant; and after a third duration, the voltage value of the second voltage reaches a second target voltage value, wherein the second time instant corresponds to a time instant at which the voltage value of the first voltage ramps to the preset voltage value.

In some examples, the method further comprises: providing the first voltage to a substrate of a second transistor that is comprised in a memory cell comprised in the memory device.

In some examples, the first voltage and the second voltage are negative voltages, and an absolute value of the first target voltage value of the first voltage is greater than an absolute value of the second target voltage value of the second voltage.

In some examples, the method further comprises: providing the first voltage to a substrate of a third transistor that is comprised in a second word line drive circuit coupled to a second unselected word line at the first time instant; and starting generating a third voltage at a third time instant, and providing the third voltage to a source terminal of the third transistor, wherein the first time instant is earlier than the third time instant. The third voltage is a negative voltage, and an absolute value of a third target voltage value of the third voltage is greater than the second target voltage value of the second voltage.

In some examples, the memory device comprises a plurality of memory blocks. Each memory block comprises a plurality of rows of memory cells and a word line coupled to each of the plurality of rows of memory cells, wherein the second unselected word line comprises a word line belonging to the same memory block as a selected word line.

In some examples, the second unselected word line further comprises at least part of word lines that are comprised in a memory block adjacent to a memory block in which the selected word line is located.

In some examples, the first unselected word line comprises an unselected word line other than the second unselected word line.

In some examples, generating the first voltage comprises: comparing a reference voltage with a first feedback voltage, and generating a first control signal according to a comparison result; and generating the first voltage according to the first control signal, wherein the first feedback voltage is a feedback voltage obtained according to the first voltage.

In some examples, the method further comprises: receiving a regulation control signal; and regulating the first voltage to a set target voltage value in response to the regulation control signal, wherein the regulation control signal is obtained according to a comparison result between the reference voltage and a second feedback voltage; and the second feedback voltage is obtained according to the first voltage, and is different from the first feedback voltage.

In some examples, the method further comprises: comparing the reference voltage with a third feedback voltage, and outputting the second enable signal according to a comparison result, wherein the third feedback voltage is obtained when the voltage value of the first voltage reaches the preset voltage value.

In some examples, the method further comprises: before the first time instant, a bit line voltage reaching a fourth target voltage value is generated to provide the bit line voltage to a corresponding bit line.

It is to be noted that the power supply method provided by the examples of the present application is based an operation and control method for the foregoing power supply circuit comprised in the memory device. Its working principle has been described in detail above, which is no longer repeated here for brevity.

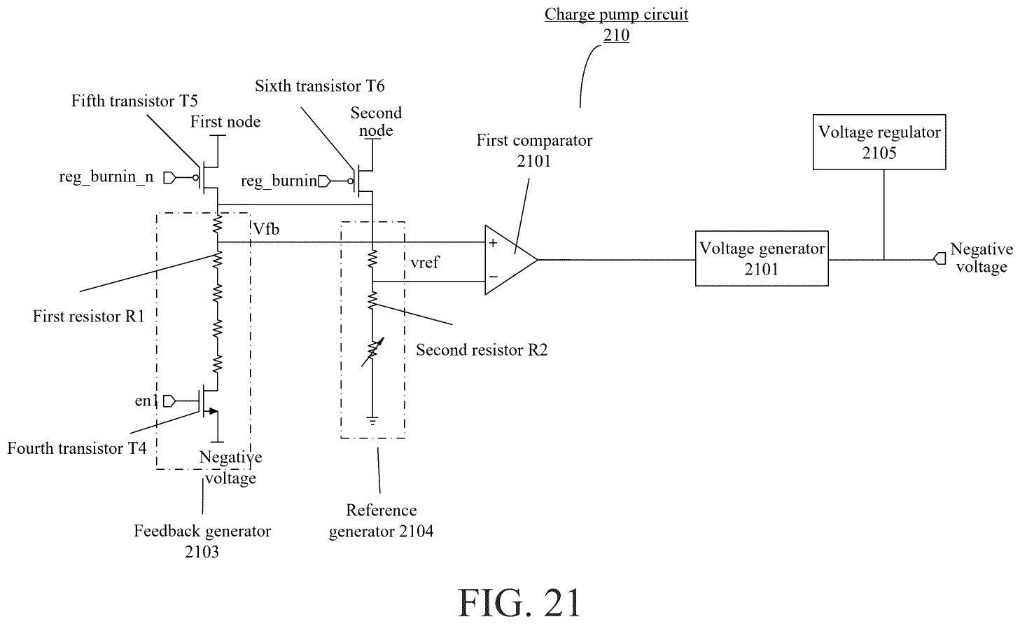

Based on the foregoing concept, as shown in FIG. 21, examples of the present application further provide a charge pump circuit 210 for a memory device, which comprises a feedback generator 2103, a reference generator 2104, a first comparator 2101, and a voltage generator 2102.

The feedback generator 2103 is connected between a first node and an output terminal of the voltage generator and has an input terminal to which a first enable signal is input, and an output terminal of the feedback generator is connected with a first input terminal of the first comparator;

The reference generator 2104 is connected between the first node and ground, and an output terminal of the reference generator is connected with a second input terminal of the first comparator;

An output terminal of the first comparator 2101 is connected with an input terminal of the voltage generator; and

The output terminal of the voltage generator 2102 outputs a negative voltage.

The first sub-voltage of the first initial voltage described above may be input to the first node.

In some examples, the feedback generator 2103 comprises: a fourth transistor, and a plurality of first resistors connected in series, wherein a first terminal of the fourth transistor is connected with the output terminal of the voltage generator, and a second terminal of the fourth transistor is connected with a first terminal of the plurality of first resistors connected in series. The fourth transistor further has a control terminal to which the first enable signal is input. The second terminal of the plurality of first resistors connected in series is connected to the first node. An output terminal led out between two of the plurality of first resistors connected in series is connected with the first input terminal of the first comparator.

In some examples, the feedback generator 2103 may further comprise a fifth transistor and a sixth transistor, wherein a first terminal of the fifth transistor is connected to the first node, and a second terminal of the fifth transistor is connected with the second terminal of the plurality of first resistors connected in series. The fifth transistor further has a control terminal to which a second control signal is input. A first terminal of the sixth transistor is connected to the second node, and a second terminal of the sixth transistor is connected with the second terminal of the plurality of first resistors connected in series. The sixth transistor further has a control terminal to which a third control signal is input.

The second sub-voltage of the first initial voltage described above may be input to the second node.

In some examples, the reference generator 2104 may comprise a plurality of second resistors connected in series, wherein a first terminal of the plurality of second resistors is connected with the second terminal of the fifth transistor and the second terminal of the sixth transistor; the second terminal of the plurality of second resistors is grounded; and an output terminal led out between two of the plurality of second resistors is connected with the second input terminal of the first comparator.

In some examples, the charge pump circuit may further comprise a voltage regulator 2105. The voltage regulator 2105 comprises at least one group of a P-type transistor and an N-type transistor. In each group, a first terminal of the P-type transistor is connected to a third node, and a second terminal of the P-type transistor is connected with a first terminal of the N-type transistor. The P-type transistor further has a control terminal to which a third enable signal is input. A second terminal of the N-type transistor is connected with the output terminal of the voltage generator. The N-type transistor further has a control terminal to which a corresponding sub-control signal is input.

In some examples, the charge pump circuit may further comprise at least one second comparator. A first input terminal of each second comparator is connected with an output terminal of the feedback generator, and a second input terminal of each second comparator is connected with the output terminal of the reference generator. An output terminal of each second comparator is connected with the control terminal of the N-type transistor of a corresponding group.

In some examples, the charge pump circuit may further comprise a third comparator. A first input terminal of the third comparator is connected with a first output terminal of the feedback generator. A second input terminal of the third comparator is connected with the output terminal of the reference generator. The output terminal of the second comparator outputs a second enable signal. A voltage output by the first output terminal has a preset voltage value. The second enable signal is configured to enable other charge pump circuits.

In some examples, the voltage generator may comprise a clock drive sub-circuit and a negative charge pump sub-circuit, wherein an input terminal of the clock drive sub-circuit is connected with the output terminal of the first comparator; an output terminal of the clock drive sub-circuit is coupled with an input terminal of the negative charge pump sub-circuit; and an output terminal of the negative charge pump sub-circuit outputs the negative voltage.

In some examples, the negative charge pump sub-circuit may comprise at least two negative charge pumps, wherein two adjacent ones of the at least two negative charge pumps are connected in series or in parallel.

It is to be noted that the charge pump circuit provided in the examples of the present application is an example structure of the first power supply circuit, the second power supply circuit, and the third power supply circuit described above, and their functions have been described in detail above, which is no longer repeated here. Vfb is a feedback voltage of the negative voltage.

Based on the foregoing concept, as shown in FIG. 22, examples of the present application further provide a memory system 220 that comprises at least one memory device 2201 as described above and a memory controller 2202. The memory controller 2202 is coupled with the memory device and controls the memory device.

As shown in FIG. 22, the memory system 220 may be comprised in an electronic apparatus 1. The electronic apparatus 1 may be a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein. As shown in FIG. 22, the electronic apparatus 1 may comprise a HOST and a memory system 220. The memory system 220 comprises a memory controller 2202 and one or more memory devices 2201. The HOST may be a processor of the electronic apparatus (e.g., a central processing unit (CPU), or a graphic processing unit (GPU)). The HOST may be configured to send or receive data to or from the memory device 2201. The memory controller 2202 is coupled to the memory device 2201 and the HOST, and is configured to control the memory device 2201. The memory controller 2202 can manage data stored in the memory device 2201 and communicate with the HOST.

The memory controller 2202 may be configured to control operations of the memory device 2201, such as read, erase, write, and refresh operations. In some implementations, the memory controller 2202 is further configured to process an error correction code (ECC) with respect to the data read from or written to the memory device 2201. The memory controller 2202 may further perform any other suitable functions as well, for example, formatting the memory device 2201.

In some examples, the memory controller 2202 and one or more of the memory devices 2201 may be integrated into various types of electronic apparatuses. For example, the memory controller 2202 may be integrated into a north bridge of a computer mainboard or directly integrated into a computer CPU, and the plurality of memory devices 2201 may be integrated into a memory module. That is to say, the memory system 220 may be implemented and packaged into different types of end electronic products.

The memory controller 2202 may send data to/receive data from the HOST, and may send a command CMD and an address ADDR to the memory device 2201. The memory controller 2202 may comprise a command generator 10, an address generator 20, an apparatus interface 30, and a host interface 40. The host interface 40 may receive the command CMD and the address ADDR from the HOST. The command generator 10 may generate an access command, a row hammer refresh command, and the like by decoding the command CMD received from the HOST, and may provide the access command and the row hammer refresh command to the memory device 2201 through the apparatus interface 30. The access command may be a signal that instructs the memory device 2201 to write or read data by accessing a row of a memory cell array 50 corresponding to the address ADDR. The row hammer refresh command may be a signal that commands the memory device 2201 to perform an additional refresh operation on a word line adjacent to a word line being intensively accessed in a short period of time. In other words, the additional refresh operation may be performed on the word line adjacent to the word line being accessed multiple times in a short period of time.

The address generator 20 in the memory controller 2202 may generate a row address and a column address to be accessed in the memory cell array 50 by decoding the address ADDR received from the host interface 40. Furthermore, the memory device 2201 may generate an address of a memory bank to be accessed when the memory cell array 50 comprises a plurality of memory banks.

Furthermore, the memory controller 2202 may provide various signals to the memory device 2201 via the apparatus interface 30 to control memory operations, such as write and read. For example, the memory controller 2202 may provide a write command to the memory device 2201. The write command is used to instruct the memory device 2201 to perform a write operation to store data into the memory device 2201.

In some examples, the memory device 2201 comprises a memory cell array 50 and a peripheral circuit 60, wherein the memory cell array 50 comprises a plurality of memory banks as shown in FIG. 3. Each memory bank comprises a plurality of memory blocks. Each memory block comprises a plurality of rows of memory cells and a plurality of columns of memory cells. Each row of memory cells is coupled with one corresponding word line, and each column of memory cells is coupled with one corresponding bit line. The peripheral circuit 60 may write data to or read data from the memory cell array 50 based on the command CMD and the address ADDR received from the memory controller 2202, or may provide a control signal CTRL for refreshing a memory cell comprised in the memory cell array 50 to a row decoding circuit and a column decoding circuit. In other words, the peripheral circuit 60 may perform all operations to process the data in the memory cell array 50. The peripheral circuit 60 may comprise: a control circuit corresponding to each memory block, for example, SA and WLD; a control circuit corresponding to each memory bank, for example, a row decoding circuit, a column decoding circuit, and the like; and a control circuit corresponding to all the memory banks, for example, a command buffer, a command decoder, an address buffer, a data input/output buffer, a mode register, and the like.

The memory device 2201 may be a random access memory (RAM), such as a DRAM, a synchronous DRAM (SDRAM), a static RAM (SRAM), a double data rate SDRAM (DDR SDRAM), a DDR2 SDRAM, a DDR3 SDRAM, a phase change RAM (PRAM), a magnetic RAM (MRAM), a resistive RAM (RRAM), and the like. In the following, only the DRAM is illustrated as an example.

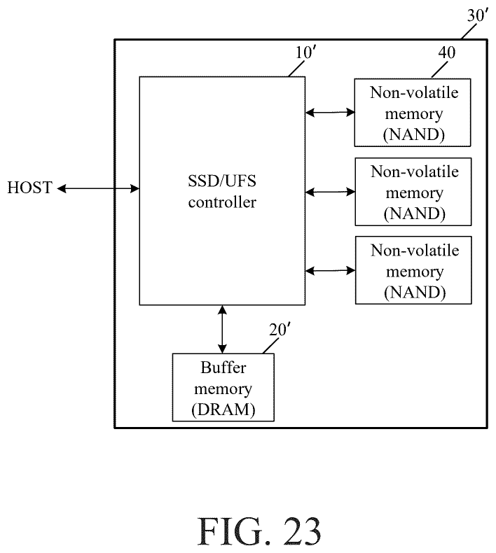

FIG. 23 is a schematic structural block diagram of an example SSD/UFS provided by an example of the present application. Here, the SSD/UFS may be understood as one of the memory systems in FIG. 22 above. In this example, the DRAM may be used as a buffer memory.

As shown in FIG. 23, an SSD/UFS 30′ may comprise an SSD/UFS controller 10′, a buffer memory 20′, and a non-volatile memory 40. The SSD/UFS controller 10′ may provide a physical connection between the HOST and the SSD/UFS 30′. That is, the SSD/UFS controller 10′ may provide an interface between the HOST and the SSD/UFS 30′ according to a bus format of the host. The SSD controller 10′ may decode instructions provided from the HOST. The SSD/UFS controller 10′ may access the non-volatile memory 40 based on a decoding result. The buffer memory 20′ may temporarily store write data provided from the HOST, or data read from the non-volatile memory 40. When the HOST sends a read request, if the data present in the non-volatile memory 40 is cached, the buffer memory 20′ may support a caching function of directly providing the cached data to the HOST. A data transfer rate in the bus format (e.g., SATA or SAS) of the host is much higher than a data transfer rate of a memory channel of the SSD/UFS 30′. That is, when a speed of interface of the host is significantly high, reduction in performance due to a speed difference may be minimized by providing the high-capacity buffer memory 20′. In addition, the buffer memory 20′ may store an address mapping table of the non-volatile memory 40. The buffer memory 20′ may include, but is not limited to, a DRAM. The non-volatile memory 40 may be disposed as a storage medium of the SSD/UFS 30′. The non-volatile memory 40 may include, but is not limited to, a NAND memory.

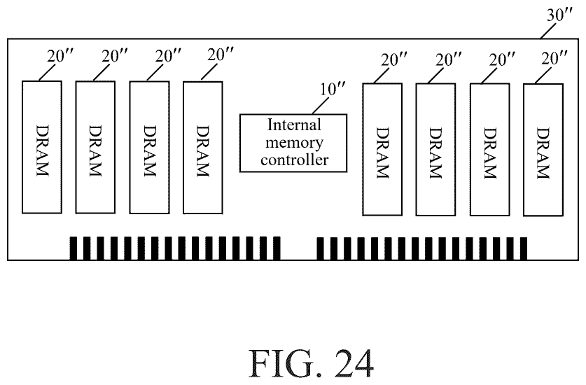

FIG. 24 is a schematic structural block diagram of an example internal memory according to an example of the present application. Here, the internal memory may be understood as one of the memory systems in FIG. 22. In this example, the DRAM may be used as a storage medium. As shown in FIG. 24, an internal memory 30″ may be easily attached or mounted to the electronic apparatus through an illustrated interface, or removed from the electronic apparatus 1. The internal memory 30″ may comprise a plurality of volatile memories 20″ (e.g., the DRAM) and an internal memory controller 10″. The internal memory 30″ of the memory module may be used to write, store, obtain (or read), and/or erase data under a controller of a processor of a computer. In some examples, the internal memory controller 10″ may communicate with the DRAM using at least one of communication protocols or technical standards generally associated with, for example, a dual-in-line memory module (DIMM), a registered DIMM (RDIMM), a load-reduced DIMM (LRDIMM), an unregistered DIMM (UDIMM), and the like. It is to be noted that both the buffer memory 20′ in FIG. 23 and the volatile memory 20″ in FIG. 24 are an application scenario of the memory device 2201 in FIG. 22, and may be applied to other application scenarios, which is not limited here. The internal memory controller is an example structure of the foregoing memory controller.

Examples of the present application further provide a computer system which may comprise the above-mentioned memory system, and a graphic processing unit coupled to the memory system and controlling the memory system. In some examples, the graphic processing unit and the memory system are integrated on the same printed circuit board (PCB).

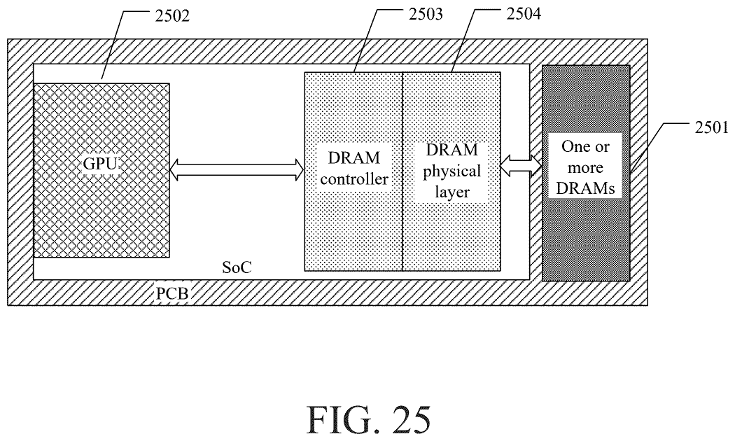

In an example, as shown in FIG. 25, FIG. 25 illustrates a schematic structural diagram of a computer system provided by examples of the present application. As shown in FIG. 25, the computer system comprises a system on chip (SoC) and one or more memory devices. The memory device comprises one or more DRAMs 2501. The SoC comprises: a graphic processing unit (GPU) 2502, a DRAM controller 2503, and a DRAM physical layer 2504, wherein the DRAM controller 2503 is responsible for the scheduling of read and write instructions and timing control of the DRAM 2501; and the DRAM physical layer 2504 is responsible for encoding the scheduled instructions according to requirements of the DRAM 2501, sending corresponding written data to the DRAM 2501, and receiving data read from the DRAM 2501. As shown in FIG. 25, the graphic processor (GPU) 2502 comprised in the computer system and the memory controller (i.e., the DRAM controller 2503) in the memory system are integrated in the same die. The die and the memory device (one or more DRAMs 2501) are integrated on the same printed circuit board. It is to be noted that the computer system, the aforementioned memory device, and the operation method belong to the same inventive concept. The computer system comprises the aforementioned memory device or memory system. Moreover, in different computer system structures, the graphic processing unit and the memory device are integrated on the same PCB, or the graphic processing unit and the memory controller are integrated on the same PCB. Therefore, the terms mentioned here have been explained in detail above and are equally applicable here, which are no longer repeated here. It should be understood that only the structures most relevant to the technical solutions of the present application are described here.

The above descriptions are only some examples of the present application, and are not used to limit the protection scope of the present application.

What is claimed is:

1. A memory device, comprising:
a memory cell array comprising a plurality of rows of memory cells and a word line coupled to each of the plurality of rows of memory cells; and
a peripheral circuit coupled with a corresponding row of memory cells via the word line, and comprising a first power supply circuit and a second power supply circuit, wherein:
the first power supply circuit is configured to start outputting a first voltage to a substrate of a first transistor that is comprised in a first word line drive circuit coupled to a first unselected word line at a first time instant; and
the second power supply circuit is configured to start outputting a second voltage to a terminal of the first transistor at a second time instant,
wherein the first time instant is earlier than the second time instant.

2. The memory device of claim 1, wherein the first voltage and the second voltage are negative voltages.

3. The memory device of claim 1, wherein the plurality of rows of memory cells comprise a plurality of memory cells, and each of the plurality of memory cells comprises a second transistor and a capacitor,
wherein a first terminal of the second transistor is connected with a terminal of the capacitor, a second terminal of the second transistor is connected with a bit line corresponding to the second transistor, and a control terminal of the second transistor is connected with a word line corresponding to the second transistor, and
wherein the first power supply circuit is further configured to provide the first voltage to a substrate of the second transistor.

4. The memory device of claim 1, wherein the first power supply circuit is further configured to start outputting the first voltage in response to a first enable signal at the first time instant; after a first duration, a voltage value of the first voltage reaches a preset voltage value; and then after a second duration, the voltage value of the first voltage reaches a first target voltage value.

5. The memory device of claim 4, wherein the second power supply circuit is further configured to start outputting the second voltage in response to a second enable signal at the second time instant; and after a third duration, a voltage value of the second voltage reaches a second target voltage value.

6. The memory device of claim 5, wherein the second time instant corresponds to a time instant at which the voltage value of the first voltage ramps to the preset voltage value.

7. The memory device of claim 4, wherein a ratio of the preset voltage value to the first target voltage value is between 50% and 90%.

8. The memory device of claim 1, wherein the peripheral circuit further comprises a third power supply circuit, wherein:
the first power supply circuit is further configured to start outputting the first voltage to a substrate of a third transistor that is comprised in a second word line drive circuit coupled with a second unselected word line at the first time instant; and
the third power supply circuit is configured to start outputting a third voltage to a terminal of the third transistor at a third time instant,
wherein the first time instant is earlier than the third time instant.

9. The memory device of claim 8, wherein the memory cell array comprises a plurality of memory blocks, and each of the plurality of memory blocks comprises the plurality of rows of memory cells and the word line coupled to each of the plurality of rows of memory cells, and
wherein the second unselected word line comprises a word line belonging to the same memory block as a selected word line.

10. The memory device of claim 9, wherein the second unselected word line further comprises at least part of word lines that are comprised in a memory block adjacent to a memory block in which the selected word line is located.

11. The memory device of claim 9, wherein the first unselected word line comprises an unselected word line other than the second unselected word line.

12. The memory device of claim 11, wherein the third voltage is a negative voltage, and an absolute value of a third target voltage value of the third voltage is greater than a second target voltage value of the second voltage.

13. The memory device of claim 1, wherein the first power supply circuit comprises a first comparator and a voltage generator, wherein:
the first comparator is configured to compare a reference voltage with a first feedback voltage, and output a first control signal according to a comparison result; the first feedback voltage is obtained according to the first voltage output by the voltage generator; and
the voltage generator is configured to output the first voltage according to the first control signal.

14. The memory device of claim 13, wherein the first power supply circuit further comprises: a feedback generator configured to receive the first voltage and output the first feedback voltage according to the first voltage; and
a reference generator configured to output the reference voltage.

15. The memory device of claim 13, wherein the voltage generator comprises a clock drive sub-circuit and a negative charge pump sub-circuit, wherein:
the clock drive sub-circuit is configured to receive the first control signal and generate a fourth control signal according to the first control signal; and
the negative charge pump sub-circuit is coupled with the clock drive sub-circuit and is configured to receive the fourth control signal and output the first voltage according to the fourth control signal.

16. A power supply method for a memory device, comprising:
starting generating a first voltage at a first time instant;
providing the first voltage to a substrate of a first transistor that is comprised in a first word line drive circuit coupled to a first unselected word line; and
starting generating a second voltage at a second time instant; and
providing the second voltage to a terminal of the first transistor,
wherein the first time instant is earlier than the second time instant.

17. The method of claim 16, further comprising:
starting generating the first voltage in response to a first enable signal at the first time instant, wherein after a first duration, a voltage value of the first voltage reaches a preset voltage value; and then after a second duration, the voltage value of the first voltage reaches a first target voltage value,
wherein a ratio of the preset voltage value to the first target voltage value is between 50% and 90%.

18. The method of claim 17, further comprising:
starting generating the second voltage in response to a second enable signal at the second time instant, wherein after a third duration, a voltage value of the second voltage reaches a second target voltage value,
wherein the second time instant corresponds to a time instant at which the voltage value of the first voltage ramps to the preset voltage value.

19. The method of claim 16, further comprising:
providing the first voltage to a substrate of a second transistor that is comprised in a memory cell comprised in the memory device.

20. A charge pump circuit, comprising: a feedback generator, a reference generator, a first comparator, and a voltage generator, wherein:
the feedback generator is connected between a first node and an output terminal of the voltage generator and has an input terminal to which a first enable signal is input, and an output terminal of the feedback generator is connected with a first input terminal of the first comparator;
the reference generator is connected between the first node and ground, and an output terminal of the reference generator is connected with a second input terminal of the first comparator;
an output terminal of the first comparator is connected with an input terminal of the voltage generator; and
the output terminal of the voltage generator outputs a negative voltage.
